(19) United States
(12) Patent Application Publication
(10) Pub. No.: US 2023/0335565 A1
(43) Pub. Date: Oct. 19, 2023

(54) ARRAY SUBSTRATE, DISPLAY PANEL AND DISPLAY DEVICE

(71) Applicant: Tianma Advanced Display Technology Institute (Xiamen) Co., Ltd., Xiamen (CN)

(72) Inventors: Xiaoli LIU, Xiamen (CN); Sitao HUO, Xiamen (CN); Xing CHEN, Xiamen (CN); Yuqin LI, Xiamen (CN)

(73) Assignee: Tianma Advanced Display Technology Institute (Xiamen) Co., Ltd., Xiamen (CN)

(21) Appl. No.: 18/210,917

(22) Filed: Jun. 16, 2023

(30) Foreign Application Priority Data
Dec. 30, 2022 (CN) 202211739275.8

(51) Int. Cl. H01L 27/12; H01L 25/16

(52) U.S. Cl. CPC H01L 27/1248; H01L 25/167

(57) ABSTRACT

Provided array substrate includes multiple transparent regions and further includes a substrate and a base layer. The base layer is disposed on a side of the substrate and includes a driving layer and a light-shielding layer disposed on the side of the driving layer facing away from the substrate, where the region in which the light-shielding layer is disposed does not overlap a transparent region along the thickness direction of the array substrate.

### CROSS-REFERENCE TO RELATED APPLICATION(S)

This application claims priority to Chinese Patent Application No. 202211739275.8 filed Dec. 30, 2022, the disclosure of which is incorporated herein by reference in its entirety.

### TECHNICAL FIELD

The present disclosure relates to the field of display technologies and, in particular, to an array substrate, a display panel, and a display device.

### BACKGROUND

A transparent display itself has a certain degree of light-transmittance, which makes a user be able to see the background behind the display while viewing the displayed picture of the display. Therefore, the transparent display is typically applied in building windows, automobile windows, shop windows, and the like.

The transparent display usually includes transparent regions and opaque regions, so that through the transparent regions, the user can view the background behind the display; and in the opaque regions, display pixels can be disposed for displaying a picture. The transparent display disposed in an automobile window is used as an example. A driver can observe road conditions in front through the transparent regions and view a navigation picture and the like displayed on the display through the opaque regions.

However, the problem of light reflection by structures such as pixel driving circuits and signal transmission wires in the opaque regions interferes with the user viewing the background behind the display, resulting in a poor transparent display effect.

### SUMMARY

The present disclosure provides an array substrate, a display panel, and a display device to solve the problem of light reflection by an opaque region and improve a transparent display effect.

The present disclosure provides an array substrate including multiple transparent regions and further including a substrate and a base layer. The base layer is disposed on a side of the substrate and includes a driving layer and a light-shielding layer disposed on the side of the driving layer facing away from the substrate, where the region in which the light-shielding layer is disposed does not overlap a transparent region along the thickness direction of the array substrate.

The present disclosure provides a display panel including multiple light-emitting elements and an array substrate, where the multiple light-emitting elements are electrically connected to the array substrate, and regions in which the multiple light-emitting elements are disposed do not overlap the transparent regions along the thickness direction of the display panel. The array substrate includes multiple transparent regions and further including a substrate and a base layer. The base layer is disposed on a side of the substrate and includes a driving layer and a light-shielding layer disposed on the side of the driving layer facing away from the substrate, where the region in which the light-shielding layer is disposed does not overlap a transparent region along the thickness direction of the array substrate.

The present disclosure provides a display device including a display panel. The display panel includes multiple light-emitting elements and an array substrate, where the multiple light-emitting elements are electrically connected to the array substrate, and regions in which the multiple light-emitting elements are disposed do not overlap the transparent regions along the thickness direction of the display panel. The array substrate includes multiple transparent regions and further including a substrate and a base layer. The base layer is disposed on a side of the substrate and includes a driving layer and a light-shielding layer disposed on the side of the driving layer facing away from the substrate, where the region in which the light-shielding layer is disposed does not overlap a transparent region along the thickness direction of the array substrate.

### BRIEF DESCRIPTION OF DRAWINGS

To illustrate technical solutions in embodiments of the present disclosure more clearly, drawings used in the description of the embodiments will be briefly described below. Apparently, the drawings described below only illustrate part of the embodiments of the present invention, and those of ordinary skill in the art may obtain other drawings based on the drawings on the premise that no creative work is done.

FIG. 1 is a top view of an array substrate according to an embodiment of the present invention;

FIG. 2 is a cross-sectional view of the array substrate taken along V-V′ in FIG. 1;

FIG. 3 is a cross-sectional view of the array substrate taken along MM′ in FIG. 1;

FIG. 4 is another cross-sectional view of the array substrate taken along MM′ in FIG. 1;

FIG. 5 is another cross-sectional view of the array substrate taken along MM′ in FIG. 1;

FIG. 6 is another cross-sectional view of the array substrate taken along MM′ in FIG. 1;

FIG. 7 is another cross-sectional view of the array substrate taken along MM′ in FIG. 1;

FIG. 8 is a sectional view of the array substrate taken along NN′ in FIG. 1;

FIG. 9 is another sectional view of the array substrate taken along NN′ in FIG. 1;

FIG. 10 is a cross-sectional view of the array substrate taken along AA′ in FIG. 1;

FIG. 11 is another cross-sectional view of the array substrate taken along AA′ in FIG. 1;

FIG. 12 is another cross-sectional view of the array substrate taken along AA′ in FIG. 1;

FIG. 13 is another cross-sectional view of the array substrate taken along AA′ in FIG. 1;

FIG. 14 is another cross-sectional view of the array substrate taken along AA′ in FIG. 1;

FIG. 15 is another cross-sectional view of the array substrate taken along AA′ in FIG. 1;

FIG. 16 is another cross-sectional view of the array substrate taken along AA′ in FIG. 1;

FIG. 17 is another cross-sectional view of the array substrate taken along AA′ in FIG. 1;

FIG. 18 is another cross-sectional view of the array substrate taken along AA′ in FIG. 1;

FIG. 19 is another cross-sectional view of the array substrate taken along AA′ in FIG. 1;

FIG. 20 is another cross-sectional view of the array substrate taken along AA′ in FIG. 1;

FIG. 21 is a top view of a display panel according to an embodiment of the present invention;

FIG. 22 is a cross-sectional view of the display panel taken along BB′ in FIG. 21; and

FIG. 23 is a structural diagram of a display device according to an embodiment of the present invention.

### DETAILED DESCRIPTION

Technical solutions in embodiments of the present disclosure are described clearly and completely in conjunction with drawings in the embodiments of the present disclosure from which the solutions of the present disclosure are better understood by those skilled in the art. Apparently, the embodiments described below are part, not all, of the embodiments of the present invention. Based on the embodiments of the present invention, all other embodiments obtained by those of ordinary skill in the art on the premise that no creative work is done are within the scope of the present invention.

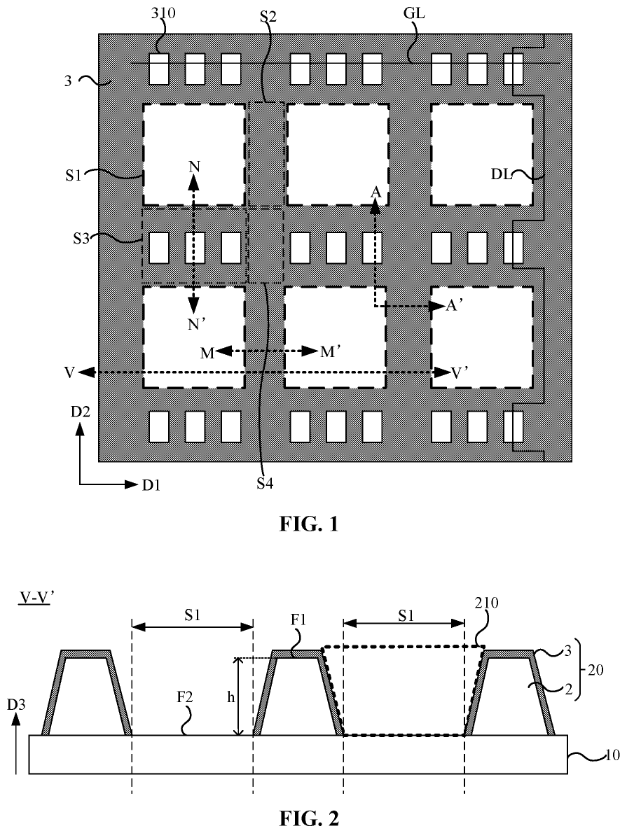

FIG. 1 is a top view of an array substrate according to an embodiment of the present invention, and FIG. 2 is a cross-sectional view of the array substrate taken along V-V′ in FIG. 1. As shown in FIGS. 1 and 2, an array substrate 100 provided by the embodiment of the present disclosure includes multiple transparent regions S1 and further includes a substrate 10 and a base layer 20, where the base layer 20 is disposed on a side of the substrate 10 and includes a driving layer 2 and a light-shielding layer 3 disposed on the side of the driving layer 2 facing away from the substrate 10, and the region in which the light-shielding layer 3 is disposed does not overlap a transparent region S1 along the thickness direction D3 of the array substrate.

The array substrate provided by the embodiment of the present disclosure is applicable in a transparent display panel, and a transparent display is performed through the multiple transparent regions S1 of the array substrate, that is, the background behind a display screen is viewed. The arrangement of the transparent regions S1 in the array substrate is not limited in the embodiment of the present invention. For example, in the array substrate, the multiple transparent regions S1 may be arranged in an array in certain regularity so that a difficulty in designing display pixels of an opaque region can be reduced.

The substrate 10 may be a glass substrate with good light-transmissive performance to suit the requirement of the transparent display panel for transmittance. Of course, the substrate 10 may be made of another material, and the material of the substrate 10 is not limited in the present application.

A sub-pixel in the transparent display panel mainly includes a light-emitting element and a pixel driving circuit for driving the light-emitting element to emit light. The driving layer 2 in the array substrate mainly includes structures such as pixel driving circuits for driving light-emitting elements to emit light and signal transmission wires for transmitting signals to the pixel driving circuits. The structure of the driving layer is described in detail subsequently, and the details are not described herein. It is to be noted that to ensure the transmittance of the transparent regions S1, the preceding structures such as the pixel driving circuits and the signal transmission wires are disposed in regions other than the transparent regions S1.

Further, referring to FIG. 2, to prevent internal structures of the driving layer 2 from reflecting light, the light-shielding layer 3 is disposed on the side of the driving layer 2 facing away from the substrate 10 in this embodiment, and the region in which the light-shielding layer 3 is disposed is configured to not overlap the transparent region S1 in the thickness direction D3 of the array substrate. With this configuration, the internal structures of the driving layer 2 can be covered by the light-shielding layer 3 so that ambient light is prevented from being directed to the interior of the driving layer, thereby avoiding the problem of light reflection. In addition, since the region in which the light-shielding layer 3 is disposed does not overlap the transparent region S1, the light-shielding layer 3 can be prevented from shielding the transparent region S1, thereby ensuring the light transmission requirement of the transparent region S1. It is to be understood that “the thickness direction D3 of the array substrate” described above refers to a direction perpendicular to the plane where the substrate 10 is disposed.

For example, the material of the light-shielding layer 3 may be a black optically clear adhesive (OCA) so that the light-shielding layer 3 can absorb the ambient light directed towards the driving layer 2 and light reflected outwards by the internal structures of the driving layer 2, thereby avoiding the problem of light reflection.

In summary, in the array substrate provided by the embodiment of the present invention, the light-shielding layer is disposed on the side of the driving layer facing away from the substrate, and the region in which the light-shielding layer is disposed is configured to not overlap the transparent region along the thickness direction of the array substrate. Thus, the internal structures of the driving layer can be covered by the light-shielding layer so that the problem of light reflection by the driving layer is avoided. In addition, the light-shielding layer can be prevented from shielding the transparent region, thereby ensuring the light transmission requirement of the transparent region.

Based on the preceding embodiment, with continued reference to FIG. 2, in some embodiments, the base layer 20 further includes multiple first openings 210; and along the direction (that is, the opposite direction of the direction D3 in FIG. 2) being from the base layer 20 to the substrate 10 and perpendicular to the plane where the substrate 10 is disposed, the first openings 210 are configured to penetrate through at least part of the base layer 20, and at least part of a first opening is disposed in a respective transparent region S1.

As described above, the pixel driving circuits and the signal transmission wires are disposed in opaque regions of the driving layer 2. It is to be understood that the pixel driving circuit needs to be constituted by multiple layers of conductive structures and an insulating layer needs to be disposed between two adjacent layers of conductive structures. Since various insulating layers may be made of different materials, the insulating layers have different refractive indices, and light is reflected at the interface between films having different refractive indices. Therefore, even if the structures such as the pixel driving circuit and the signal transmission wire are not disposed in the driving layer of the transparent region S1 and only the multiple insulating layers are retained, the loss of the transmittance is also caused by the reflection of the light between the insulating layers having the different refractive indices. In the embodiment of the present invention, corresponding to the transparent regions S1, the first openings 210 are disposed in the array substrate and at least part of the first opening 210 is disposed in the respective transparent region S1. Compared with still retaining the insulating layers in the transparent region S1, this configuration can further improve the transmittance of the transparent region S1.

Specifically, referring to FIG. 2, the first opening 210 may be formed according to the following steps: an opening (the opening penetrates through at least part of films of the driving layer) corresponding to the transparent region S1 is processed in the driving layer after the preparation of the driving layer is completed; the light-shielding layer 3 is prepared and patterned to remove the light-shielding layer of the transparent region S1 such that the base layer 20 is formed; and the light-shielding layer 3 covers at least part of sidewalls of the driving layer in the base layer 20 and sidewalls of the base layer 20 enclose the first opening 210. The sidewalls of the base layer 20 include at least sidewalls of the light-shielding layer 3. For example, FIG. 2 only illustrates an example in which the sidewalls of the driving layer are completely covered by the light-shielding layer 3. In this case, the sidewalls of the base layer 20 are the sidewalls of the light-shielding layer 3, and the sidewalls of the light-shielding layer 3 enclose the first opening 210. It is to be understood that if the light-shielding layer 3 covers only part of the sidewalls of the driving layer, the sidewalls of the base layer 20 include the sidewalls of the light-shielding layer 3 and partial sidewalls of the driving layer which are not covered by the light-shielding layer 3 and the first opening 210 is collectively enclosed by the sidewalls of the light-shielding layer 3 and the partial sidewalls of the driving layer.

It is to be noted that FIG. 2 only illustrates an example in which the first openings 210 penetrate through the base layer 20. In other embodiments, the first openings 210 may be configured to penetrate through part of films in the base layer 20 along the direction (that is, the opposite direction of the direction D3 in FIG. 2) being from the base layer 20 to the substrate 10 and perpendicular to the plane where the substrate 10 is disposed, which is not limited in the embodiment of the present invention. In this embodiment, the first openings 210 are configured to completely penetrate through the base layer 20, which is conducive to increasing the transmittance of the transparent region S1 as much as possible.

With continued reference to FIG. 2, in some embodiments, the opening area of the first opening gradually increases along the direction (that is, the direction D3 in FIG. 2) being from the substrate 10 to the base layer 20 and perpendicular to the plane where the substrate 10 is disposed. The opening area of the first opening 210 specifically refers to the opening area of the first opening 210 on a cross section parallel to the substrate 10. Briefly, the opening area of the first opening 210 gradually increases from bottom to top. Specifically, when the opening is processed in the driving layer 2, the opening area of the opening of the driving layer is controlled to gradually increase from bottom to top so that the opening area of the first opening 210 of the base layer 20 can keep gradually increasing from bottom to top after the light-shielding layer 3 is formed. This configuration is conducive to covering the sidewalls of the driving layer 2 by the light-shielding layer 3 so that a good light-shielding effect is achieved. In addition, referring to FIG. 2, the transparent region S1 is delimited by the outermost edges of the sidewalls of the light-shielding layer 3 which are used for forming the first opening 210. The opening area of the first opening 210 is configured to gradually increase from bottom to top so that the first opening 210 can have a portion outside the transparent region S1. Thus, a light transmission channel is not limited to the region delimited by the transparent region S1. The light can also be transmitted by the portion of the first opening 210 outside the transparent region S1, which is conducive to enlarging the area of the light transmission channel, increasing the amount of transmitted light, and improving a transparent display effect.

It is to be noted that FIG. 2 only simply illustrates an example in which a section of the first opening 210 perpendicular to the plane where the substrate 10 is disposed is in the shape of an inverted trapezoid, which is not limited. As long as it is ensured that the opening area of the first opening 210 gradually increases from bottom to top, the shape of the section of the first opening 210 perpendicular to the plane where the substrate 10 is disposed is not particularly limited in the embodiment of the present invention.

As described above, the material of the light-shielding layer 3 may be the black OCA. In this case, the light-shielding layer 3 mainly needs to be prepared by the following process: the black liquid optically clear adhesive (LOCA) is coated on the driving layer having the opening, then the black OCA is cured, and finally a black OCA corresponding to the transparent region S1 is removed through a photolithography process. Studies have found that the black OCA which is on the driving layer and close to the opening flows along the sidewalls of the driving layer into the low-lying opening when the black LOCA is coated, and therefore, if the black OCA flows into the opening excessively, an insufficient black OCA are easily retained on the driving layer, which causes an excessively thin light-shielding layer and further causes the problem of film breakage of the light-shielding layer. Further, referring to FIG. 2, it is readily understood in conjunction with life common sense (for example, accumulating sand) that the narrower the island-shaped driving layer adjacent to the first opening 210 (that is, the narrower a substrate below an accumulated material), the more easily the black OCA on the driving layer flows into the opening of the driving layer, the greater the inter-surface height difference h between the upper surface F1 of the driving layer and a flow plane F2 (the flow plane F2 in FIG. 2 is the upper surface of the substrate 10) in the first opening 210 (that is, the higher the substrate below the accumulated material), the more easily the black OCA flows downward, and the more easily the problem of film breakage of the light-shielding layer 3 occurs.

In conjunction with the specific structures of the array substrate, the embodiments of the present disclosure provide several possible solutions below to avoid the problem of film breakage of the light-shielding layer.

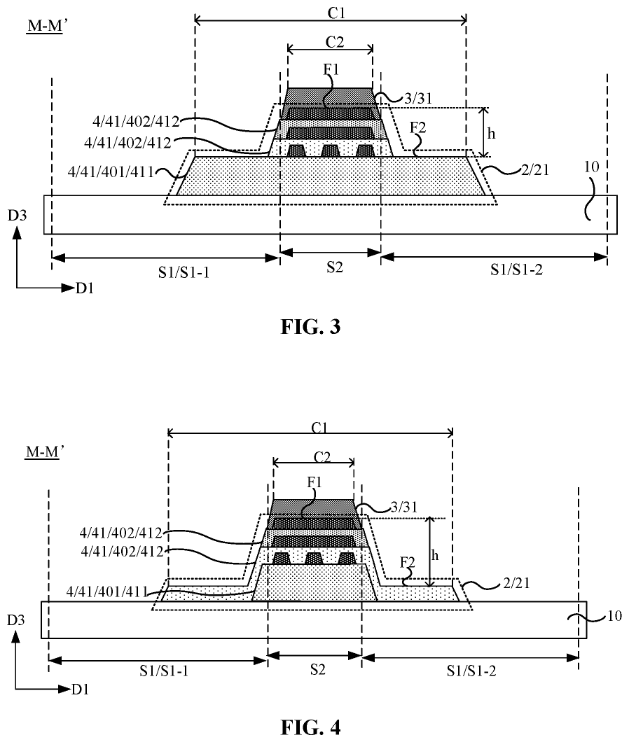

FIG. 3 is a cross-sectional view of the array substrate taken along MM′ in FIG. 1. As shown in FIGS. 1 and 3, in some embodiments, the array substrate further includes a first circuit region S2 adjacent to the transparent region S1 along a first direction D1, where the light-shielding layer 3 includes a first light-shielding sub-portion 31, the driving layer 2 includes a first driving sub-portion 21, and along the thickness direction D3 of the array substrate, the region in which the first light-shielding sub-portion 31 is disposed and the region in which the first driving sub-portion 21 is disposed each overlap the first circuit region S2; and the width (such as C1) of at least part of the first driving sub-portion 21 along the first direction D1 is greater than the width (such as C2) of the first light-shielding sub-portion 31 along the first direction D1;

The first direction D1 is parallel to the substrate 10. The array substrate includes multiple scan lines for providing scan signals for the pixel driving circuit and multiple data lines providing data signals for the pixel driving circuit. In some embodiments, the first direction D1 is parallel to the extension direction of the scan lines, or the first direction D1 is parallel to the extension direction of the data lines. For example, FIG. 1 illustrates an example in which the first direction is parallel to the extension direction of a data line DL.

The first circuit region S2 is used for disposing the signal transmission wires, and at least one type of signal transmission wire may be disposed in the first circuit region S2. The type of signal transmission wire in the first circuit region S2 is not limited in the embodiment of the present invention.

It is to be noted that the first circuit region S2 refers to a circuit region adjacent to the transparent region S1 along the first direction D1, and the array substrate may include other circuit regions in addition to the first circuit region S2. For example, the other circuit regions may not be adjacent to the transparent region S1, or the other circuit regions may be adjacent to the transparent region S1 along other directions, which is not limited in the embodiment of the present invention. It is to be further noted that in the array substrate, all of regions adjacent to each transparent region S1 along the first direction D1 may be first circuit regions S2, or part of regions adjacent to each transparent region S1 along the first direction D1 may be first circuit regions S2 and part of the regions adjacent to each transparent region S1 along the first direction D1 may be regions having other functions, which is not limited in the embodiment of the present invention.

The first light-shielding sub-portion 31 is a portion of the light-shielding layer 3 which covers the first circuit region S2. In some embodiments, the region of an orthographic projection of the first light-shielding sub-portion 31 on the substrate 10 coincides with the region of an orthographic projection of the first circuit region S2 on the substrate 10. The first driving sub-portion 21 is a portion which is in the driving layer 2 and overlaps the first circuit region S2. In this embodiment, the width of the at least part of the first driving sub-portion 21 along the first direction D1 is greater than the width of the first light-shielding sub-portion 31 along the first direction D1 so that the region of an orthographic projection of the first driving sub-portion 21 on the substrate 10 is larger than the region of the orthographic projection of the first circuit region S2 on the substrate 10.

It is to be noted that the at least part of the first driving sub-portion 21 specifically refers to at least part of films in the first driving sub-portion 21, that is, the width of the at least part of the films in the first driving sub-portion 21 along the first direction D1 is greater than the width of the first light-shielding sub-portion 31 along the first direction D1.

Referring to FIG. 3, it is to be further noted that since films in the first light-shielding sub-portion 31 and the films in the first driving sub-portion 21 each have inclined sidewalls, the first light-shielding sub-portion 31 at different thicknesses has different widths in the first direction D1, and the films in the first driving sub-portion 21 also have different widths in the first direction D1. For ease of comparison, in FIG. 3, the width C2 of the side of the first light-shielding sub-portion 31 farthest from the substrate 10 in the first direction D1 is selected as the width of the first light-shielding sub-portion 31, and the width of each film in the first driving sub-portion 21 is subject to the width (such as C1) of the side of the film farthest from the substrate 10 in the first direction D1.

Referring to FIG. 3, the first circuit region S2 is adjacent to a transparent region S1-1 and a transparent region S1-2 along the first direction D1. Since the first circuit region S2 is used for disposing the signal transmission wires and the widths of the signal transmission wires are relatively narrow and the spacing between adjacent signal transmission wires is relatively small, the width of the first circuit region S2 in the first direction D1 is relatively narrow, and the problem of film breakage of the light-shielding layer 3 in the first circuit region S2 easily occurs. FIG. 2 and FIG. 3 are compared. In comparison with the case where the flow plane F2 is the upper surface of the substrate 10, in this embodiment (as shown in FIG. 3), the width (such as C1) of the at least part of the first driving sub-portion 21 in the first direction D1 is configured to be greater than the width (such as C2) of the first light-shielding sub-portion 31 in the first direction D1 so that a widened portion of the first driving sub-portion can be used for increasing the height at which the flow plane F2 in the first opening 210 is disposed. Thus, the step between the upper surface F1 of the driving layer and the flow plane F2 is reduced, which is equivalent to the reduction of the height of the substrate of the accumulated materials. In this manner, when the black LOCA is coated for the preparation of the light-shielding layer 3, the black OCA on the driving layer 2 in the first circuit region S2 can be slowed down to flow downwards along the sidewalls of the driving layer 2, thereby ensuring the film thickness of the light-shielding layer 3 in the first circuit region S2 and preventing the film of the light-shielding layer 3 in the first circuit region S2 from being broken.

It is to be noted that a film whose width is increased along the first direction D1 may be any film in the first driving sub-portion, which is not limited in the embodiment of the present invention. It is to be further noted that another first circuit region S2 or another functional region may be on the side of the transparent region S1-1 facing away from the first circuit region S2 in FIG. 3, and similarly, another first circuit region S2 or another functional region may be on the side of the transparent region S1-2 facing away from the first circuit region S2 in FIG. 3, which is not limited in the embodiment of the present invention.

With continued reference to FIG. 3, in some embodiments, the driving layer 2 includes multiple insulating layers 4, where at least one of the insulating layers 4 include a first insulating sub-portion 41, and the region in which the first insulating sub-portion 41 is disposed overlaps the first circuit region S2 along the thickness direction D3 of the array substrate; and the width (such as C1) of the first insulating sub-portion 41 along the first direction D1 is greater than the width C2 of the first light-shielding sub-portion 31 along the first direction D1.

The region in which the first insulating sub-portion 41 are disposed overlaps the first circuit region S2 in the thickness direction D3 of the array substrate. In other words, the first insulating sub-portion 41 is an insulating layer in the first driving sub-portion 21. As can be seen in FIG. 3, the widened portion of the first driving sub-portion 21 not only overlaps the first circuit region S2 but also extends to the transparent regions S1. Since the transmittance of the insulating layer is higher than the transmittance of a metal structure, the width of at least one insulating layer 4 in the first driving sub-portion 21 along the first direction D1, that is, the width (such as C1) of the first insulating sub-portion 41 along the first direction D1, is configured to be greater than the width C2 of the first light-shielding sub-portion 31 along the first direction D1 in this embodiment, which can alleviate the problem of film breakage of the light-shielding layer 3 in the first circuit region S2 and reduce the impact on the transmittance of the transparent region S1.

For example, as shown in FIG. 3, the multiple insulating layers 4 may include an inorganic insulating layer 401, and the inorganic insulating layer 401 includes a first inorganic insulating sub-portion 411, where the region in which the first inorganic insulating sub-portion 411 is disposed overlaps the first circuit region S2 along the thickness direction D3 of the array substrate, and the width of at least one of the first inorganic insulating sub-portion 411 along the first direction D1 is greater than the width C2 of the first light-shielding sub-portion 31 along the first direction D1. With this configuration, the width of the inorganic insulating layer corresponding to the first circuit region S2 along the first direction D1 may be increased, which alleviates the problem of film breakage of the light-shielding layer 3 in the first circuit region S2 and reduces the impact on the transmittance of the transparent region S1. The first inorganic insulating sub-portion 411 may be understood as an inorganic insulating layer in the first driving sub-portion 21. The first inorganic insulating sub-portion 411 belongs to a first insulating sub-portion 41 and is made of an inorganic material.

It is to be noted that when two or more inorganic insulating layers exist, in some embodiments, the width of at least one of first inorganic insulating sub-portions 411 along the first direction D1 is greater than the width of the first light-shielding portion 31 along the first direction D1. For example, FIG. 3 illustrates an example in which the first driving sub-portion 21 includes one layer of the first inorganic insulating sub-portion 411 and the width C1 of the first inorganic insulating sub-portion 411 along the first direction D1 is greater than the width C2 of the first light-shielding sub-portion 31 along the first direction D1. It is to be understood that the greater the number of first inorganic insulating sub-portions each having a width along the first direction D1 greater than the width of the first light-shielding sub-portion 31 along the first direction D1, the closer the flow plane F2 is to the upper surface F1 of the driving layer, which is more conducive to slowing down the black OCA to flow downwards along the sidewalls of the driving layer 2 and achieves a better effect of alleviating the problem of film breakage of the light-shielding layer 3.

FIG. 4 is another cross-sectional view of the array substrate taken along MM′ in FIG. 1. As shown in FIG. 4, in some embodiments, the multiple insulating layers 4 include organic insulating layers 402, where at least one of the organic insulating layers 402 include a first organic insulating sub-portion 412, and the region in which the first organic insulating sub-portion 412 is disposed overlaps the first circuit region S2 along the thickness direction D3 of the array substrate; and the width (such as C1) of the first organic insulating sub-portion 412 along the first direction D1 is greater than the width C2 of the first light-shielding sub-portion 31 along the first direction D1.

A first organic insulating sub-portion 412 may be understood as an organic insulating layer in the first driving sub-portion 21. The first organic insulating sub-portion 412 belongs to a first insulating sub-portion 41 and is made of an organic material.

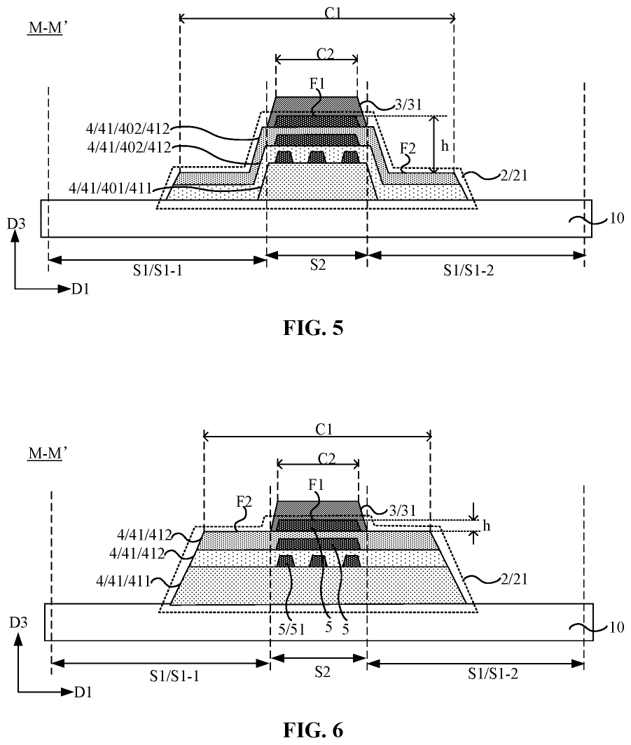

It is to be noted that the multiple insulating layers 4 may include at least one organic insulating layer 402. FIG. 3 only illustrates an example in which the insulating layers 4 include two insulating layers 402. In other embodiments, the driving layer may include one or more organic insulating layers, which is not limited in the embodiment of the present invention. Accordingly, the width of the at least one organic insulating layer 402 in the first driving sub-portion 21 along the first direction D1 may be greater than the width C2 of the first light-shielding sub-portion 31 along the first direction D1, and FIG. 4 only illustrates an example in which the width (such as C1) of one layer of the first organic insulating sub-portion 412 along the first direction D1 is greater than the width C2 of the first light-shielding sub-portion 31 along the first direction D1. This configuration manner is not a limitation. For example, FIG. 5 is another cross-sectional view of the array substrate taken along MM′ in FIG. 1. As shown in FIG. 5, in other embodiments, the width (such as C1) of each of multiple layers of the first organic insulating sub-portions 412 along the first direction D1 may be configured to be greater than the width C2 of the first light-shielding sub-portion 31 along the first direction D1 so that the height at which the flow plane F2 is disposed is further increased, the inter-surface height difference h between the upper surface F1 of the driving layer in the first circuit region S2 and the flow plane F2 is reduced, and the problem of film breakage of the light-shielding layer 3 in the first circuit region S2 is alleviated.

For example, the material of the organic insulating layer may be, for example, a transparent OCA. The width of the first organic insulating sub-portion 412 along the first direction D1 is configured to be greater than the width C2 of the first light-shielding sub-portion 31 along the first direction D1 so that the first organic insulating sub-portion 412 has portions extending to the transparent regions, which can alleviate the problem of film breakage of the light-shielding layer 3 in the first circuit region S2. In addition, since the transparent OCA has higher transmittance, the impact on the transmittance of the transparent region S1 is relatively small.

In addition, in the driving layer, various organic insulating layers may be typically made of the same material, but various inorganic insulating layers have different refractive indices. In comparison with the increase of the width of the inorganic insulating layer corresponding to the first circuit region S2 along the first direction D1, the width of each of the first organic insulation layers corresponding to the first circuit region S2 along the first direction D1 is increased so that the interfaces between the films which have the different refractive indices and through which the light passes during propagation can be reduced. Thus, the light reflection is reduced so that the transmittance of the transparent region S1 is ensured.

It is to be noted that the preceding embodiments only illustrate an example in which the width of the first organic insulating sub-portion 412 in the first direction D1 or the width of the first inorganic insulating sub-portion 411 in the first direction D1 is increased to be greater than the width of the first light-shielding sub-portion 31 along the first direction D1. This configuration is not a limitation. FIG. 6 is another cross-sectional view of the array substrate taken along MM′ in FIG. 1. As shown in FIG. 6, in other embodiments, in the case where the transmittance of transparent region S1 satisfies a requirement, the width (such as C1) of the first inorganic insulating sub-portion 411 along the first direction D1 and the width (such as C1) of the first organic insulating sub-portion 412 along the first direction D1 are each greater than the width C2 of the first light-shielding sub-portion along the first direction D1. In this manner, the height at which the flow plane F2 is disposed can be increased as much as possible, the inter-surface height difference h between the upper surface F1 of the driving layer in the first circuit region S2 and the flow plane F2 is reduced, and the problem of film breakage of the light-shielding layer 3 in the first circuit region S2 is better alleviated.

In summary, in the preceding embodiments, the width of the at least part of the first driving sub-portion 21 corresponding to the first circuit region S2 is increased such that the problem of film breakage of the light-shielding layer 3 in the first circuit region S2 is alleviated. Another solution is provided below.

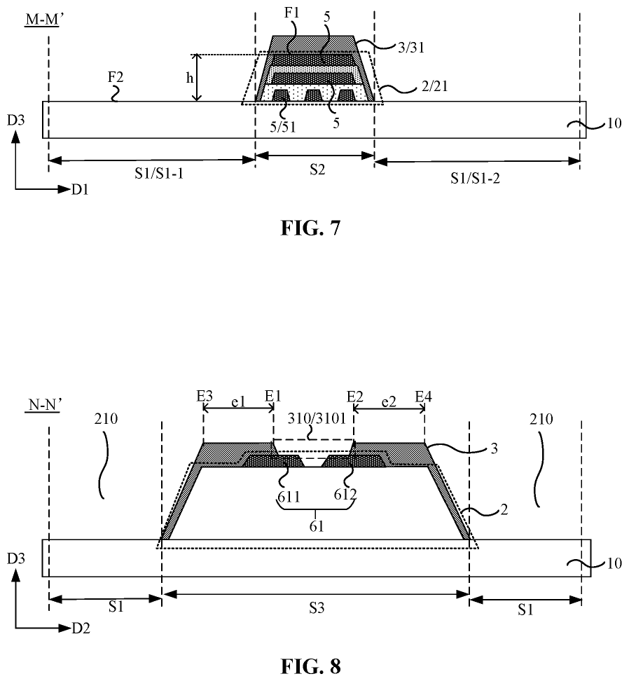

FIG. 7 is another cross-sectional view of the array substrate taken along MM′ in FIG. 1. As shown in FIGS. 1 and 7, in some embodiments, the array substrate further includes the first circuit region S2 adjacent to the transparent region S1 along the first direction D1, where the driving layer 2 includes a first wiring layer including a first wire S1 extending along a second direction D2, and the region in which the first wiring layer is disposed overlaps the first circuit region S2 and does not overlap the transparent region S1 along the thickness direction D3 of the array substrate; and the first wire S1 in the first circuit region S2 is in contact with the substrate 10. The first direction D1 and the second direction D2 intersect with each other and are each parallel to the substrate 10.

The first wiring layer may be understood as the wiring layer closest to the side of the substrate 10 among multiple layers of signal transmission wires 5 in the first circuit region S2. For example, when the first direction D1 is parallel to the extension direction of the scan lines, the first wire S1 in the first wiring layer may be, for example, a data line, and the data line generally extend along the second direction D2. In other embodiments, when the first direction D1 is parallel to the extension direction of the data line, the first wire S1 in the first wiring layer may be, for example, the scan line, and the scan line generally extends along the second direction D2.

In comparison of FIG. 6 with FIG. 7, the insulating layer 4 originally exists between the first wire S1 in the first circuit region S2 and the substrate 10, and the first wire S1 in the first circuit region S2 is configured to be in contact with the substrate 10 in this embodiment, which is implemented specifically through the removal of the insulating layer between the first wire S1 in the first circuit region S2 and the substrate 10 during preparation. Specifically, before the first wiring layer is formed, the insulating layer in the first circuit region S2 is patterned so that the substrate 10 in the first circuit region S2 is exposed, then the first wiring layer is formed, and in this manner, it may be implemented that the first wire S1 in the first circuit region S2 is in contact with the substrate 10. With the preceding solution, the inter-surface height difference h between the upper surface F1 of the driving layer in the first circuit region S2 and the flow plane F2 can also be reduced so that the problem of film breakage of the light-shielding layer 3 in the first circuit region S2 can be alleviated.

FIG. 8 is a sectional view of the array substrate taken along NN′ in FIG. 1. As shown in FIGS. 1 and 8, in some embodiments, the array substrate further includes a first device region S3 adjacent to the transparent region S1 along the second direction D2, where the driving layer 2 includes a connection electrode layer including multiple groups of connection electrodes 61, the region in which the connection electrodes 61 are disposed overlaps the first device region S3 along the thickness direction D3 of the array substrate, the light-shielding layer includes multiple groups of second openings 310, and one group of connection electrodes 61 are exposed by a respective group of second openings 310.

The second direction D2 is parallel to the substrate 10. For example, the second direction D2 may be parallel to the extension direction of the scan lines, or the second direction D2 may be parallel to the extension direction of the data lines. FIG. 1 only illustrates an example in which the second direction D2 is parallel to the extension direction of the data line DL.

The first device region S3 is used for disposing the pixel driving circuit. For example, a 7T1C pixel driving circuit is commonly used at present, where “T” denotes a thin-film transistor and “C” denotes a storage capacitor. The 7T1C pixel driving circuit is a relatively mature technology, so it will not be described too much here. Multiple pixel driving circuits may be disposed in the first device region S3 and are configured to drive multiple light-emitting elements to emit light. The number of pixel driving circuits and the arrangement manner of the pixel driving circuits in the first device region S3 are not particularly limited in the embodiment of the present invention.

It is to be noted that the first device region S3 refers to a device region adjacent to the transparent region S1 along the second direction D2, and the array substrate may further include other device regions in addition to the first device region S3. For example, the other device regions may not be adjacent to the transparent region S1, or the other device regions may be adjacent to the transparent region S1 along other directions, which is not limited in the embodiment of the present invention. It is to be further noted that in the array substrate, all of regions adjacent to each transparent region S1 along the second direction D2 may be first device regions S3, or part of regions adjacent to each transparent region S1 along the second direction D2 may be first device regions S3 and part of the regions adjacent to each transparent region S1 along the second direction D2 may be regions having other functions (for example, the preceding first circuit regions S2), which is not limited in the embodiment of the present invention.

As shown in FIG. 8, the driving layer 2 includes the connection electrode layer including the multiple groups of connection electrode 61 (the only one group of connection electrodes are shown in FIG. 8), and the region in which the connection electrodes 61 are disposed overlaps the first device region S3 along the thickness direction D3 of the array substrate, in other words, at least part of the connection electrodes 61 are disposed in the first device region S3. The connection electrodes 61 are configured to be electrically connected to the pixel driving circuits and are also configured to be electrically connected to the light-emitting elements to implement that the light-emitting elements are electrically connected to the pixel driving circuits. The pixel driving circuit is disposed on the side of a connection electrode 61 in the driving layer 2 facing the substrate 10, and the structure of the pixel driving circuit is described by way of example subsequently.

For example, a light-emitting element may be a micro light-emitting diode. Accordingly, the one group of connection electrodes 61 may include two connection electrodes (a first connection electrode 611 and a second connection electrode 612 as shown in FIG. 8). One of the two connection electrodes is configured to be electrically connected to the anode of the micro light-emitting diode and the other connection electrode is configured to be electrically connected to the cathode of the micro light-emitting diode. The micro light-emitting diode is transferable onto the array substrate through mass transfer. One micro light-emitting diode is electrically connected to the one group of connection electrodes 61 and further electrically connected to the pixel driving circuit.

Further, the light-shielding layer 3 is disposed on the side of the driving layer facing away from the substrate 10, and the light-shielding layer 3 is provided with the second openings 310 so that the connection electrodes 61 can be exposed to facilitate the subsequent electrical connection between the connection electrodes 61 and the light-emitting elements. Specifically, the number of groups of second openings 310 is the same as the number of groups of connection electrodes 61, and the one group of connection electrodes 61 are exposed by the respective group of second openings 310. The specific number of openings in one group of second openings 310 is not limited in the embodiment of the present disclosure as long as at least part of each connection electrode in a respective group of connection electrodes 61 can be exposed.

With continued reference to FIG. 8, in some embodiments, at least one first device region S3 is adjacent to two first openings 210 along the second direction D2; and along the second direction D2, a second opening 310 includes a first edge E1 and a second edge E2 which are opposite to each other. The sides of two adjacent first openings 210 which are farthest from the substrate 10 separately include a third edge E3 and a fourth edge E4. The third edge E3 and the fourth edge E4 are opposite to each other and are disposed in the first device region S3. The first edge E1 is adjacent to the third edge E3 along the second direction D2, the second edge E2 is adjacent to the fourth edge E4 along the second direction D2, and the distance e1 between the first edge E1 and the third edge E3 along the second direction D2 is equal to the distance e2 between the second edge E2 and the fourth edge E4 along the second direction D2.

The first edge E1 and the second edge E2 specifically refer to the outermost edges of all the openings in the one group of second openings 310 in the second direction D2. In this embodiment, the distance el between the first edge E1 and the third edge E3 in the second direction D2 is configured to be equal to the distance e2 between the second edge E2 and the fourth edge E4 in the second direction D2. Thus, the black OCA flows downwards along the sidewalls of the driving layer 2 in the first device region S3 at a substantially uniform degree when the black LOCA is coated for the preparation of the light-shielding layer, which is conducive to ensuring the thickness uniformity of the light-shielding layer 3 on two opposite sides of the second opening 310 along the second direction D2. The light-emitting element (the micro light-emitting diode) is transferred onto the array substrate through a stamp. If the thicknesses of the light-shielding layer 3 on the two opposite sides of the second opening 310 along the second direction D2 are not uniform, the stamp is inclined when pressed against the array substrate, and then the light-emitting element is inclined, affecting the bonding yield between the light-emitting element and the connection electrode 61. The solution in this embodiment is conducive to ensuring the thickness uniformity of the light-shielding layer 3 on the two opposite sides of the second opening 310 along the second direction D2 so that it is conducive to ensuring that the stamp can be kept in a level state when bonding the light-emitting element, thereby improving the bonding yield between the light-emitting element and the connection electrode 61.

It is to be noted that the distance el between the first edge E1 and the third edge E3 may not be completely equal to the distance e2 between the second edge E2 and the fourth edge E4 and a certain error range is allowed due to the limitation of technique accuracy.

With continued reference to FIG. 8, in some embodiments, the connection electrode 61 includes the first connection electrode 611 and the second connection electrode 612; and a group of second openings 310 include at least one second sub-opening 3101, and at least one of the first connection electrode 611 or the second connection electrode 612 is exposed by one second sub-opening 3101.

For example, FIG. 8 illustrates an example in which the one group of second openings 310 includes the second sub-opening 3101. In this case, the first connection electrode 611 and the second connection electrode 612 are exposed by the second sub-opening 3101 at the same time, and two opposite edges of the second sub-opening 3101 along the second direction D2 are the first edge E1 and the second edge E2 separately.

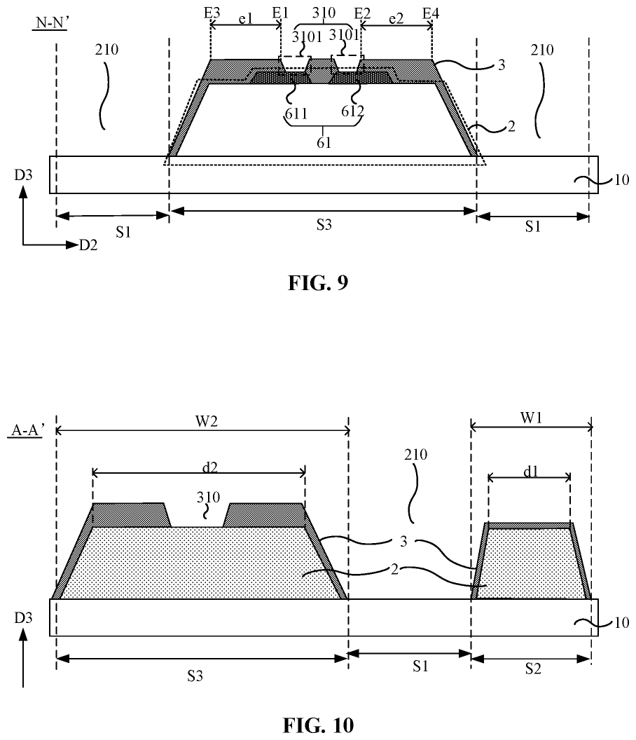

FIG. 9 is another sectional view of the array substrate taken along NN′ in FIG. 1. As shown in FIG. 9, in other embodiments, in some embodiments, the one group of second openings 310 include two second sub-openings 3101, where the first connection electrode 611 is exposed by one of the two second sub-opening 3101, the second connection electrode 612 is exposed by the other second sub-opening 3101, and in this case, two outermost opposite edges of the two second sub-openings 3101 along the second direction D2 are the first edge E1 and the second edge E2.

FIG. 10 is a cross-sectional view of the array substrate taken along AA′ in FIG. 1. As shown in FIGS. 1 and 10, in some embodiments, the array substrate includes the first device region S3 and the first circuit region S2 which are adjacent to the transparent region S1, where the width of the first circuit region S2 is W1 along the direction from the transparent region S1 to the first circuit region S2, and the width of the first device region S3 is W2 along the direction from the transparent region S1 to the first device region S3, where W1<W2.

One first device region S3 and one first circuit region S2 may be adjacent to the same transparent region S1 along the same direction or may be adjacent to the same transparent region S1 along different directions, which is not limited in the embodiment of the present invention. FIG. 1 only illustrates an example in which the first circuit region S2 and the first device region S3 are adjacent to the transparent region S1 along the different directions. In other embodiments, the first circuit region S2 and the first device region S3 may be arranged in another manner.

As described above, the pixel driving circuit is disposed in the first device region S3, and the signal transmission wires are disposed in the first circuit region S2. The pixel driving circuit typically occupies a larger area than the signal transmission wires. Therefore, after the pixel driving circuit in the first device region S3 and the signal transmission wires in the first circuit region S2 are avoided such that the first opening 210 is formed, the width W2 of the first device region S3 tends to be greater than the width W1 of the first circuit region S2. Therefore, the width d1 of the upper surface of the driving layer 2 in the first circuit region S2 is less than the width d2 of the upper surface of the driving layer 2 in the first device region S3. Based on the preceding explanation, it is to be understood that the light-shielding layer 3 in the first circuit region S2 is more prone to the problem of film breakage than the light-shielding layer 3 in the first device region S3 when the black LOCA is coated for the preparation of the light-shielding layer 3. To avoid the film breakage of the light-shielding layer 3 in the first circuit region S2, the use amount of the black OCA can be increased so that the overall thickness of the light-shielding layer 3 can be increased. However, the width d2 of the upper surface of the driving layer 2 in the first device region S3 is relatively great, which is conducive to the accumulation of the black OCA. Therefore, in the case where the thickness of the light-shielding layer 3 in the first circuit region S2 reaches a requirement, the light-shielding layer 3 in the first device region S3 may be caused to be excessively thick. Further, when the light-emitting element is bonded, the connection electrodes in the first device region S3 and the light-emitting element may be in poor contact or no contact with each other, which affects the bonding yield. As a result, it is unable to attend to everything, and it is difficult to give consideration to both the bonding yield and the problem of film breakage. To alleviate the problem of film breakage of the light-shielding layer 3 in the first circuit region S2 and ensure the bonding yield of the light-emitting element in the first device region S3, the following solutions are proposed by the embodiments of the present invention.

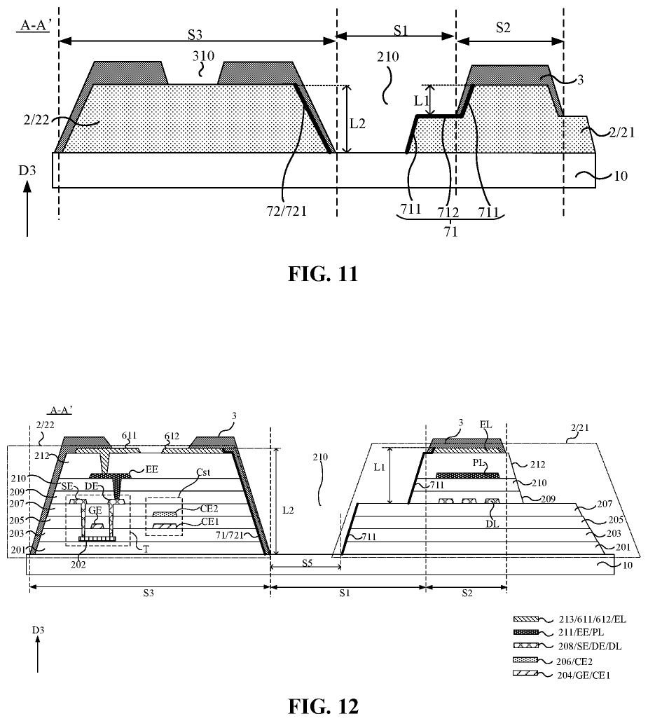

FIG. 11 is another cross-sectional view of the array substrate taken along AA′ in FIG. 1. As shown in FIG. 11, the driving layer 2 includes the first driving sub-portion 21 at least partially disposed in the first circuit region S2, where the first driving sub-portion 21 includes a first sidewall 71 including at least one first sidewall sub-portion 711, the first sidewall sub-portion 711 continuously inclines towards the first circuit region S2, and a projection height of the first sidewall sub-portion 711 farthest from the substrate 10 in the thickness direction D3 of the array substrate is L1; and the driving layer 2 includes a second driving sub-portion 22 at least partially disposed in the first device region S3, where the second driving sub-portion 22 includes a second sidewall 72 including one second sidewall sub-portion 721, the second sidewall sub-portion 721 continuously inclines towards the first device region S3, and a projection height of the second sidewall sub-portion 721 in the thickness direction D3 of the array substrate is L2; where L1<L2.

The first sidewall 71 includes the at least one first sidewall sub-portion 711 and the first sidewall sub-portion 711 continuously inclines towards the first circuit region S2, which may be understood as the case where a portion of the first sidewall 71 keeping continuously inclining towards the first circuit region S2 belongs to the same first sidewall sub-portion 711. Once a horizontal sidewall appears, the horizontal sidewall does not belong to the first sidewall sub-portion 711, and two sidewalls which are connected by the horizontal sidewall and continuously incline towards the first circuit region S2 belong to different first sidewall sub-portions 711 separately. For example, the preceding horizontal sidewall has an extension length of at least 5 μm. A horizontal sidewall having a length of less than 5 μm may be caused by a technique accuracy problem. In this case, the horizontal sidewall may be ignored.

For example, FIG. 11 illustrates an example in which the first sidewall 71 includes two first sidewall sub-portions 711. One horizontal sidewall 712 is included between the two first sidewall sub-portions 711. The horizontal sidewall 712 and the two first sidewall sub-portions 711 collectively constitute the first sidewall 71 of the first driving sub-portion 21. In other embodiments, the first sidewall 71 may include one or more first sidewall sub-portions 711, which is not limited in the embodiment of the present invention.

The second sidewall 72 includes the second sidewall sub-portion 721, and the second sidewall sub-portion 721 continuously inclines towards the first device region S3, which may be understood as the case where the second sidewall 72 keeps continuously inclining towards the first device region S3 constantly. Alternatively, although a horizontal sidewall may be included by the second sidewall 72, the horizontal sidewall has an extension length of less than 5 μm and may be ignored. In this case, the second sidewall 72 may be considered to include only one second sidewall sub-portion 721 continuously inclining towards the first device region S3.

Further, after the driving layer 2 is formed and the opening is processed on the driving layer, the black LOCA may be coated for the preparation of the light-shielding layer 3. After the black LOCA is coated, the uppermost black OCA of the driving layer 2 in the first circuit region S2 flows downwards along the first sidewall 71 of the first driving sub-portion 21. The projection height L1 of the first sidewall sub-portion 711 farthest from the substrate 10 in the thickness direction D3 of the array substrate may be understood as the step height of a leveling step of the black OCA in the first circuit region S2. Similarly, the uppermost black OCA of the driving layer 2 in the first device region S3 flows downwards along the second sidewall 72 of the second driving sub-portion 22. The projection height L2 of the second sidewall sub-portion 721 in the thickness direction D3 of the array substrate may be understood as the height of a leveling step of the black OCA in the first device region S3. It is to be understood that when the black OCA flows along the inclined sidewall to the horizontal sidewall, the flow velocity of the black OCA is reduced. Therefore, the lower the leveling step, the more quickly the flow velocity of the black OCA can be reduced, which is more conducive to the accumulation of the black OCA on the driving layer.

Since the width of the first circuit region S2 is less than the width of the first device region S3, the black OCA on the driving layer 2 in the first circuit region S2 flows downwards more easily than the black OCA on the driving layer 2 in the first device region S3. In this embodiment, the projection height L1 of the first sidewall sub-portion 711 farthest from the substrate 10 on the array substrate is configured to be less than the projection height L2 of the second sidewall sub-portion 721 on the array substrate so that the height of the leveling step of the black OCA in the first circuit region S2 is less than the height of the leveling step of the black OCA in the first device region S3, which is conducive to slowing down the flow of the black OCA on the driving layer in the first circuit region S2 and is further conducive to ensuring the thickness of the light-shielding layer 3 on the driving layer in the first circuit region S2 and avoiding the film breakage of the light-shielding layer 3 in the first circuit region S2. In addition, it is unnecessary to increase the overall thickness of the light-shielding layer 3 to avoid the problem of film breakage of the light-shielding layer 3 in the first circuit region S2. Thus, the excessively thick light-shielding layer 3 in the first device region S3 can be prevented from affecting the bonding of the light-emitting element, and the bonding yield is ensured.

Based on the preceding design concept, the embodiment for implementing that L1<L2 is further described below in detail in conjunction with the specific structures of the array substrate.

As shown in FIG. 1, in some embodiments, the first circuit region S2 is configured to be adjacent to the transparent region S1 along the first direction D1, and the first device region S3 is configured to be adjacent to the transparent region S1 along the second direction D2, where the first direction D1 and the second direction D2 intersect with each other and are each parallel to the substrate. With this configuration, the signal transmission wires in the first circuit region S2 may extend along the second direction D2 and are wound to the first device region S3 to be electrically connected to the pixel driving circuit in each first device region S3, to transmit desired electrical signals to the pixel driving circuit. Thus, the arrangement of device regions and circuit regions in the array substrate is more regular.

In addition, referring to FIG. 1, the array substrate further includes an intersection region S4 which is disposed between adjacent first device regions S3 or adjacent first circuit regions S2 and is not adjacent to the transparent region S1. It is to be noted that the pixel driving circuit may be disposed in the intersection region S4 so that a pixel density is increased and a display effect is improved. Of course, in other embodiments, the pixel driving circuit may be not disposed in the intersection region, and the intersection region is only used for disposing the signal transmission wires, which is not limited in the embodiment of the present invention.

The first direction D1 and the second direction D2 may be parallel to the extension direction of the scan lines and the extension direction of the data lines, respectively. For example, the first direction D1 is parallel to the extension direction of the scan lines and the second direction D2 is parallel to the extension direction of the data lines. Alternatively, the first direction D1 is parallel to the extension direction of the data lines and the second direction D2 is parallel to the extension direction of the scan lines. For example, FIG. 1 only illustrates an example in which the first direction D1 is parallel to the extension direction of a scan line GL and the second direction D2 is parallel to the extension direction of the data line DL. In this case, the data line DL overlaps the first circuit region S2 and may transmit the data signals to the pixel driving circuit in the first device region S3.

FIG. 12 is another cross-sectional view of the array substrate taken along AA′ in FIG. 1. As shown in FIG. 12, in some embodiments, the region in which the driving layer is disposed in the first device region S3 does not overlap the transparent region S1 along the thickness direction D3 of the array substrate; and at least one film of the driving layer in the first circuit region S2 extends to the transparent region S1.

With this configuration, the film in the first circuit region S2 extending to the transparent region S1 may be used such that the first sidewall of the first driving sub-portion includes at least two first sidewall sub-portions 711 continuously inclining towards the first circuit region S2, and the horizontal sidewall is formed between two adjacent first sidewall sub-portions 711. Thus, the projection height L1 of the first sidewall sub-portion 711 farthest from the side of the substrate 10 in the thickness direction D3 of the array substrate may be less than the projection height L2 of the second sidewall sub-portion 721 in the thickness direction D3 of the array substrate. That is, the height of the leveling step of the black OCA in the first circuit region S2 is less than the height of the leveling step of the black OCA in the first device region S3, which is conducive to alleviating the problem of film breakage of the light-shielding layer 3 in the first circuit region S2, can avoid the excessively thick light-shielding layer 3 in the first device region S3, and ensures the bonding yield of the light-emitting element. For the specific principle, reference may be made to the explanation of related content in FIG. 11. The details are not repeated here.

In some embodiments, the driving layer includes the multiple insulating layers, and at least one insulating layer in the first circuit region S2 extends to the transparent region S1.

As described above, the pixel driving circuit is disposed in the first device region S3. Referring to FIG. 12, in an embodiment, the driving layer in the first device region S3 may specifically include a spacer layer 201, an active layer 202, a gate insulating layer 203, a gate metal layer 204, a first interlayer insulating layer 205, a capacitor metal layer 206, a second interlayer insulating layer 207, a first metal layer 208, a third interlayer insulating layer 209, a first planarization layer 210, a second metal layer 211, a second planarization layer 212, and a third metal layer 213 which are disposed on the substrate 10 and stacked in sequence. The spacer layer (e.g., a barrier) is an insulating layer, and the material thereof may be silicon oxide. The spacer layer is used for improving the adhesion of an upper film, which can prevent the organic layer 202 from being directly prepared on the glass substrate 10 and peeling. The material of the organic layer 202 may be, for example, low-temperature polycrystalline silicon (LTPS), and of course, other types of active layer materials may be selected according to requirements for the characteristics of the thin-film transistor, which is not limited in the embodiment of the present invention. The material of the gate insulating layer 203 may be the silicon oxide, or the gate insulating layer 203 may be a laminate constituted by the silicon oxide and nitrogen oxide. The material of the first interlayer insulating layer 205 may be silicon nitride. The second interlayer insulating layer 207 may be a laminate constituted by the silicon oxide and the silicon nitride. The material of the third interlayer insulating layer 209 may be the silicon nitride. The spacer layer 201, the gate insulating layer 203, the first interlayer insulating layer 205, the second interlayer insulating layer 207, and the third interlayer insulating layer 209 are all inorganic insulating layers. The first planarization layer 210 and the second planarization layer 212 are organic films, and the specific material thereof may be the transparent OCA such as acrylic-based or epoxy-based organic materials. In the first device region S3, the gate metal layer 204 may be used for forming at least the gate GE of a thin-film transistor T, and one capacitor plate CE1 of a storage capacitor Cst may also be formed; the capacitor metal layer 206 may be used for forming the other capacitor plate CE2 of the storage capacitor Cst, and two capacitor plates are disposed opposite to each other; and the first metal layer 208 may be used for forming the source SE and drain DE of the thin-film transistor T, the second metal layer 211 may be used for forming a transition electrode EE, the third metal layer 213 may be used for forming the connection electrodes (611 and 612), and the connection electrode 611 is electrically connected to the lower thin-film transistor T through the transition electrode EE.

It is to be noted that the preceding metal conductive layers such as the first metal layer, the second metal layer, the third metal layer, the gate metal layer, and the capacitor metal layer may be formed of other conductive materials in other embodiments, which is not limited in the embodiment of the present invention.

As shown in FIG. 12, the driving layer 2 (that is, the second driving sub-portion 22) in the first device region S3 does not overlap the transparent region S1. In this region, the light-shielding layer 3 covers the upper surface of the second driving sub-portion 22 and sidewalls of the second driving sub-portion 22 and the connection electrodes (611 and 612) in the first device region S3 are exposed so that a good light-shielding effect can be achieved, and the problem of light reflection is avoided. In addition, external light can be prevented from entering the active layer 202 of the thin-film transistor T and causing a threshold drift, thereby ensuring the drive capability of the pixel driving circuit. Since the first device region S3 is relatively wide, the second sidewall 72 of the second driving sub-portion may include one second sidewall sub-portion 721, and when the black OCA is coated to form the light-shielding layer 3, the height (L2) of a leveling step of the black OCA on the second driving sub-portion 22 is the vertical height between the upper surface of the third metal layer 213 and the upper surface of the substrate 10.

Further, in this embodiment, the at least one film of the driving layer 2 in the first circuit region S2 extends to the transparent region S1 such that it is implemented that L1<L2. Therefore, the first circuit region S2 and the first device region S3 have the same insulating layers except films (such as the active layer 202 and each metal layer) having the function of conducting electricity. The films having the function of conducting the electricity in the first circuit region S2 may be configured according to the wire configuration requirement of the first circuit region S2.

For example, referring to FIGS. 1 and 12, when the first circuit region S2 and the transparent region S1 are adjacent to each other along the first direction D1, the first device region S3 and the transparent region S1 are adjacent to each other along the second direction D2, the first direction D1 is parallel to the extension direction of the scan line GL, and the second direction D2 is parallel to the extension direction of the data line DL, the driving layer 2 in the first circuit region S2 may include the data line DL in addition to the preceding insulating layers such as the spacer layer 201, the gate insulating layer 203, the first interlayer insulating layer 205, the second interlayer insulating layer 207, the third interlayer insulating layer 209, the first planarization layer 210, and the second planarization layer 212, and for example, the data line DL may be disposed in the first metal layer 208; and the first circuit region S2 may further include a PVDD power signal line PL and a PVEE power signal line EL which may be provided in the second metal layer 211 and the third metal layer 213, respectively. It is to be noted that FIG. 12 only illustrates an example in which the PVDD power signal line PL is disposed in the second metal layer 211 and the PVEE power signal line EL is disposed in the third metal layer 213. In other embodiments, the PVDD power signal line PL may be disposed in the third metal layer 213 and the PVEE power signal line EL may be disposed in the second metal layer 211.

Further, in some embodiments, at least one of the spacer layer 201, the gate insulating layer 203, the first interlayer insulating layer 205, the second interlayer insulating layer 207, the third interlayer insulating layer 209, the first planarization layer 210, or the second planarization layer 212 in the first circuit region S2 extends to the transparent region S1. For example, reference is made to FIG. 12 which illustrates an example in which the spacer layer 201, the gate insulating layer 203, the first interlayer insulating layer 205, and the second interlayer insulating layer 207 extend to the transparent region S1. Many possible embodiments exist, which are not shown one by one here. The insulating layers extending to the transparent region S1 may be properly selected by those skilled in the art according to actual situations.

In this embodiment, the at least one insulating layer in the first circuit region is configured to extend to the transparent region so that the first sidewall 71 of the first driving sub-portion 21 can have the at least two first sidewall sub-portions 711 continuously inclining towards the first circuit region S2, and the horizontal sidewall is formed between the two adjacent first sidewall sub-portions 711 so that the step height (that is, L1) of the leveling step of the black OCA in the first circuit region S2 is less than the step height (that is, L2) of the leveling step in the first device region S3. Thus, the black OCA on the driving layer 2 in the first circuit region S2 is slowed down to flow downwards, which is conducive to alleviating the problem of film breakage of the light-shielding layer 3 in the first circuit region S2 and can prevent the bonding yield of the light-emitting element in the first device region S3 from being affected.

In addition, as can be seen from FIG. 12, in this embodiment, the at least one insulating layer of the driving layer 2 in the first circuit region S2 extends to the transparent region S1 so that the opening area (such as the area of the region shown by S5 in FIG. 12) on the side of the first opening 210 closest to the substrate 10 is smaller than the area of the region in which the transparent region S1 is disposed. However, the insulating layer has relatively high transmittance. Therefore, even if part of the insulating layer is disposed in the transparent region S1, the impact on the transmittance of the transparent region S1 is relatively small.

In some embodiments, the multiple insulating layers include the organic insulating layers, and at least one of the organic insulating layers in the first circuit region S2 extends to the transparent region S1.

It is to be understood that the greater the number of insulating layers in the first circuit region S2 extending to the transparent region S1, the less the step height (that is, L1) of the leveling step of the black OCA in the first circuit region S2, which is more conducive to alleviating the problem of film breakage of the light-shielding layer 3 in the first circuit region S2. However, from the perspective of the transmittance, the greater the number of insulating layers extending to the transparent region S1, the greater the probability that the light is reflected at the interface between the insulating layers having the different refractive indices. As a result, the loss of transmittance is increased accordingly. Therefore, insulating layers in the first circuit region S2 which have the same refractive index may be selected to extend into the transparent region S1.

The transmittance of an organic insulating layer is higher than the transmittance of the inorganic insulating layer, and the organic insulating layers in the driving layer may typically be made of the same material. Therefore, the at least one of the organic insulating layers in the first circuit region S2 may be configured to extend to the transparent region S1. In addition, the adhesion force of the black OCA on the organic insulating layer is relatively great, and the at least one of the organic layers in the first circuit region S2 extends to the transparent region S1 so that the exposed surface of the organic insulating layer can become a horizontal sidewall, which is conducive to further reducing the flow velocity of the black OCA and reducing the risk of film breakage of the light-shielding layer 3 in the first circuit region S2.

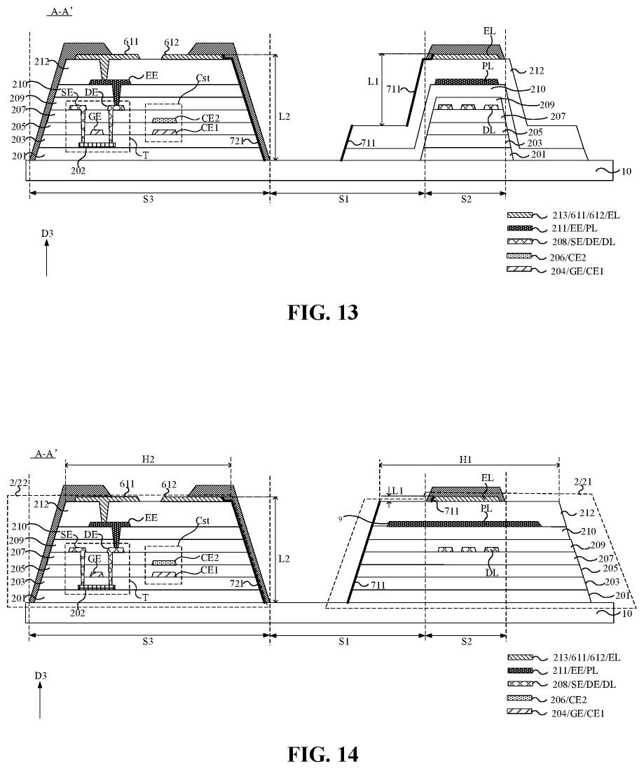

For example, FIG. 13 is another cross-sectional view of the array substrate taken along AA′ in FIG. 1. As shown in FIG. 13, referring to FIG. 13, in this embodiment, the organic insulating layers in the driving layer include the first planarization layer 210 and the second planarization layer 212, and at least one of the first planarization layer 210 or the second planarization layer 212 may be configured to extend to the transparent region S1. FIG. 13 only illustrates an example in which the first planarization layer 210 and the second planarization layer 212 each extend to the transparent region S1.

In some embodiments, the driving layer includes transparent wiring layers, and at least one of the transparent wiring layers in the first circuit region S2 extends to the transparent region S1.

Specifically, at least part of the signal transmission wires in the first circuit region S2 may be transparent wires, and the material of the transparent wires may be, for example, indium tin oxide. Since the transmittance of the transparent wires is relatively high, the at least one of the transparent wiring layers in the first circuit region S2 extends to the transparent region S1 so that the step height (that is, L1) of the leveling step of the black OCA on the part of the driving layer in the first circuit region S2 can be reduced. Thus, the problem of film breakage of the light-shielding layer 3 in the first circuit region S2 is alleviated, the bonding yield of the light-emitting element in the first device region S3 is ensured, and the impact on the transmittance of the transparent region S1 is reduced. In addition, the width of a transparent wire in the transparent wiring layer can be increased, thereby reducing the resistance of the transparent wire and power consumption.

For example, FIG. 14 is another cross-sectional view of the array substrate taken along AA′ in FIG. 1. Referring to FIGS. 1 and 14, when the first circuit region S2 and the transparent region S1 are adjacent to each other along the first direction D1, the first device region S3 and the transparent region S1 are adjacent to each other along the second direction D2, the first direction D1 is parallel to the extension direction of the scan line GL, and the second direction D2 is parallel to the extension direction of the data line DL, and in some embodiments, the PVDD power signal line PL and/or the PVEE power signal line EL in the first circuit region S2 are transparent wires and extend to the transparent region S1. FIG. 14 illustrates an example in which all the insulating layers in the first circuit region S2 and the PVDD power signal line in the first circuit region S2 extend to the transparent region S1. This configuration is conducive to forming the PVDD power signal line on a relatively flat film, thereby reducing the risk of wire breakage of the PVDD signal line.

Referring to FIG. 14, in some embodiments, the driving layer includes the first driving sub-portion 21 and the second driving sub-portion 22, where the region in which the first driving sub-portion 21 is disposed overlaps the first circuit region S2 along the thickness direction D3 of the array substrate, and the region in which the second driving sub-portion 22 is disposed overlaps the first device region S3 along the thickness direction D3 of the array substrate. The maximum width of the first driving sub-portion, along the direction from the transparent region S1 to the first circuit region S2, is H1, and the maximum width of the second driving sub-portion, along the direction from the transparent region S1 to the first device region S3, is H2, and H1≥H2.

The first driving sub-portion 21 and the second driving sub-portion 22 each include multiple layers of films. Referring to FIGS. 1 and 14, using an example in which the direction from the transparent region S1 to the first circuit region S2 is the first direction D1 and the direction from the transparent region S1 to the first device region S3 is the second direction D2, the maximum width H1 of the first driving sub-portion 21 along the first direction is greater than or equal to the maximum width H2 of the second driving sub-portion 22 along the second direction, which can be specifically understood as the case where the width of at least one film of the first driving sub-portion 21 along the first direction is greater than or equal to the width of the corresponding film in the first device region S3 along the second direction.

Specifically, since the at least one film in the first driving sub-portion 21 extends to the transparent region S1, the width of the film along the first direction is greater than the width of another unwidened film in the first driving sub-portion along the first direction. The width of the film which is in the first driving sub-portion 21 and extends to the transparent region S1 along the first direction may be configured to be greater than or equal to the width of the film in the first device region S3 along the second direction. This configuration is conducive to ensuring that the horizontal sidewall between the adjacent first sidewall sub-portions 711 has a sufficient width to slow down the black OCA on the driving layer in the first circuit region S2 to flow downwards along the first sidewall sub-portions 711, which is conducive to accumulating the black OCA on the driving layer in the first circuit region S2, ensures the film thickness of the light-shielding layer 3 in the first circuit region S2, and reduces the risk of film breakage.

For example, referring to FIG. 14, in FIG. 14, each insulating layer in the first circuit region S2 extends to the transparent region, and the width of any insulating layer in the first circuit region along the first direction is approximately equal to the width of the corresponding insulating layer in the first device region along the second direction. For example, the width (H1) of the second planarization layer 212 in the first circuit region along the first direction is equal to the width (H2) of the second planarization layer 212 in the first device region along the second direction, and the width of each insulating layer under the second planarization layer and in the first circuit region is also equal to the width of each insulating layer under the second planarization layer and in the first device region. This configuration is conducive to improving the uniformity of the overall film thickness of the light-shielding layer.

In summary, in the preceding description, the at least one film in the first circuit region is configured to extend to the transparent region so that it is implemented that the height of the leveling step of the black OCA in the first circuit region is less than the height of the leveling step of the black OCA in the first device region. When the array substrate is prepared, specifically, an opening size of each film may be controlled so that it is implemented that the first sidewall of the driving layer includes the at least two first sidewall sub-portions.

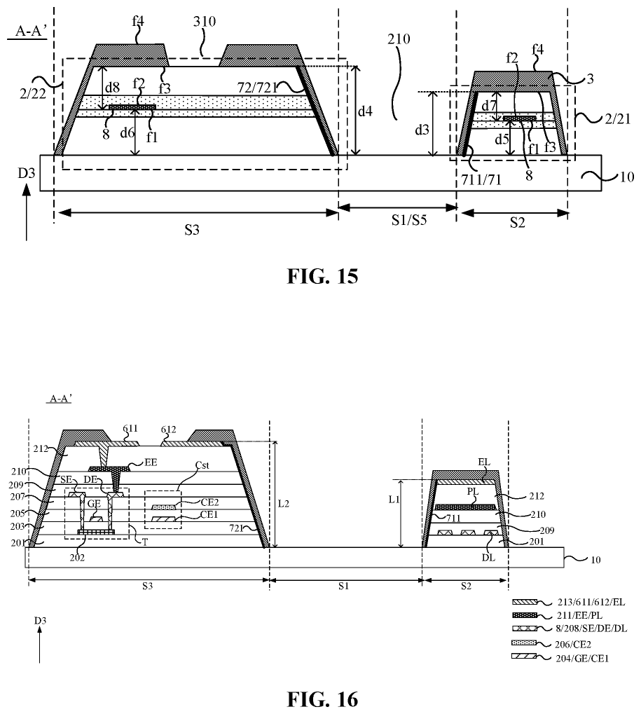

FIG. 15 is another cross-sectional view of the array substrate taken along AA′ in FIG. 1. As shown in FIG. 15, in some embodiments, the thickness d3 of the driving layer 2 in the first circuit region S2 along the thickness direction D3 of the array substrate is smaller than the thickness d4 of the driving layer 2 in the first device region S3 along the thickness direction D3 of the array substrate. Specifically, as shown in FIG. 15, in this embodiment, the first sidewall 71 of the first driving sub-portion 21 may include one first sidewall sub-portion 711 continuously inclining towards the first circuit region S2, that is, the first sidewall sub-portion 711 is farthest from the side of the substrate 10. The projection height (L1) of the first sidewall sub-portion 711 in the thickness direction D3 of the array substrate is equal to the thickness d3 of the driving layer in the first circuit region S2. Similarly, the projection height (L2) of the second sidewall sub-portion 721 of the second driving sub-portion 22 in the thickness direction D3 of the array substrate is equal to the thickness d4 of the driving layer in the first device region S3. Therefore, in this embodiment, the thickness of the driving layer in the first circuit region S2 is configured to be smaller than the thickness of the driving layer in the first device region S3 so that it can also be implemented that the projection height L1 of the first sidewall portion 711 farthest from the substrate 10 in the thickness direction D3 of the array substrate is less than the projection height L2 of the second sidewall portion 721 in the thickness direction D3 of the array substrate. That is, the height of the leveling step of the black OCA in the first circuit region S2 is less than the height of the leveling step of the black OCA in the first device region S3, thereby achieving the effect of reducing the risk of film breakage of the light-shielding layer 3 in the first circuit region S2 and preventing the bonding yield of the light-emitting element in the first device region S3 from being affected.

In addition, referring to FIG. 15, when the thickness d3 of the driving layer 2 in the first circuit region S2 is smaller than the thickness d4 of the driving layer 2 in the first device region S3 and the first sidewall 71 of the first driving sub-portion may include the first sidewall sub-portion 711 continuously inclining towards the first circuit region S2. In some embodiments, the side (such as the region S5 in FIG. 15) of the first opening 210 closest to the substrate 10 is configured to coincide with the region in which the transparent region S1 is disposed. With this configuration, only the first opening 210 may be included in the transparent region S1, no other film exists in the transparent region S1, and the first device region S3 and the first circuit region S2 also include part of the first opening 210 so that the problem of film breakage of the light-shielding layer 3 in the first circuit region S2 is solved, the bonding yield of the light-emitting element in the first device region S3 is ensured, no loss to the transmittance of the transparent region S1 can be caused, and the transmittance of the transparent region S1 can be effectively ensured.

In conjunction with the arrangement manner in which the first circuit region S2 and the transparent region S1 are adjacent to each other along the first direction D1, the first device region S3 and the transparent region S1 are adjacent to each other along the second direction D2, the first direction D1 is parallel to the extension direction of the scan lines, and the second direction D2 is parallel to the extension direction of the data lines, a possible embodiment of this solution is described below by way of example.

Referring to FIG. 15, in some embodiments, the driving layer includes a first conductive layer 8. Along the thickness direction D3 of the array substrate, the distance d5 between the first conductive layer 8 in the first circuit region S2 and the substrate 10 is less than the distance d6 between the first conductive layer 8 in the first device region S3 and the substrate 10.

The first conductive layer 8 is a film provided with conductive structures in both the first device region S3 and the first circuit region S2. The distance d5 between the first conductive layer 8 and the substrate 10 in the first circuit region S2 is configured to be less than the distance d6 between the first conductive layer 8 and the substrate 10 in the first device region S3 so that it can be implemented that the thickness of the driving layer 3 in the first circuit region S2 is smaller than the thickness d of the driving layer in the first device region S3. Thus, it is implemented that the projection height L1 of the first sidewall portion 711 farthest from the substrate 10 in the thickness direction D3 of the array substrate is less than the projection height L2 of the second sidewall portion 721 in the thickness direction D3 of the array substrate, thereby achieving the effect of reducing the risk of film breakage of the light-shielding layer 3 in the first circuit region S2 and preventing the bonding yield of the light-emitting element in the first device region S3 from being affected.

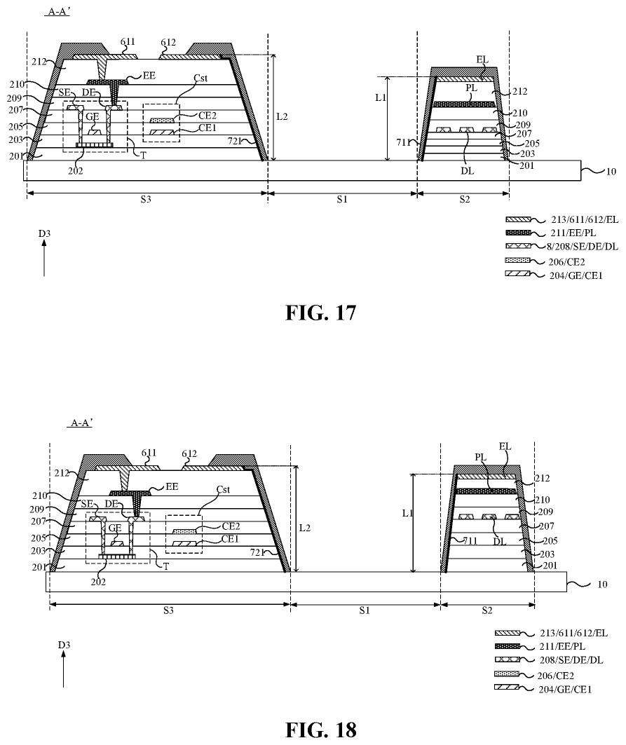

For example, FIG. 16 is another cross-sectional view of the array substrate taken along AA′ in FIG. 1. As shown in FIG. 16, the array substrate includes the thin-film transistor T and data lines DL, and the thin-film transistor includes the source SE and the drain DE, where the region in which the thin-film transistor T is disposed overlaps at least the first device region S3 along the thickness direction D3 of the array substrate, and the region in which the data lines DL are disposed overlaps the first circuit region S2 along the thickness direction D3 of the array substrate. In some embodiments, the first conductive layer 8 is at least used for forming the source SE of the thin-film transistor T, the drain DE of the thin-film transistor T, and the data lines DL. In other words, the first conductive layer 8 is the first metal layer 208. When the first conductive layer 8 is the film in which the source SE, the drain DE, and the data lines DL are disposed, the multiple insulating layers exist between the source SE and the substrate 10 in the first device region S3, such as the spacer layer 201, the gate insulating layer 203, the first interlayer insulating layer 205, and the second interlayer insulating layer 207, and these insulating layers are indispensable in the first device region S3. However, in the first circuit region S2, referring to FIG. 14, there may be no other wires between the data lines DL and the substrate 10. Therefore, the preceding insulating layers may exist or not exist in the first circuit region S2, and the at least one insulating layer may be removed or thinned such that it is implemented that the distance between the first conductive layer 8 and the substrate 10 in the first circuit region S2 is less than the distance between the first conductive layer 8 and the substrate 10 in the first device region S3.

With continued reference to FIG. 16, in some embodiments, the driving layer includes multiple insulating layers between the first conductive layer 8 and the substrate 10; and among the multiple insulating layers, the number of insulating layers in the first circuit region S2 is smaller than the number of the insulating layers in the first device region S3. Specifically, in this embodiment, the at least one insulating layer between the first conductive layer 8 and the substrate 10 in the first circuit region S2 may be removed so that it is implemented that the number of the insulating layers between the first conductive layer 8 and the substrate 10 in the first circuit region S2 is smaller than the number of the insulating layers between the first conductive layer 8 and the substrate 10 in the first device region S3. Thus, the thickness of the part of the driving layer in the first circuit region S2 is smaller than the thickness of the driving layer in the first device region S3, thereby achieving the effect of reducing the risk of film breakage of the light-shielding layer 3 in the first circuit region S2 and preventing the bonding yield of the light-emitting element in the first device region S3 from being affected.

For example, referring to FIG. 16, when the first conductive layer 8 includes the data lines DL, at least one of the spacer layer 201, the gate insulating layer 203, the first interlayer insulating layer 205, or the second interlayer insulating layer 207 between the data lines DL and the substrate 10 in the first circuit region S2 may be removed. For example, in comparison of the first device region S3 with the first circuit region S2 shown in FIG. 16, FIG. 16 illustrates an example in which the gate insulating layer 203, the first interlayer insulating layer 205, and the second interlayer insulating layer 207 between the data lines DL and the substrate 10 in the first circuit region S2 are removed and only the spacer layer 201 is retained. In this manner, the problems such as the film breakage of the light-shielding layer in the first circuit region S2 are alleviated, and the data lines DL can be prevented from being in direct contact with the substrate 10, which is conducive to ensuring the adhesion of the data lines.

When the first conductive layer 8 includes the data lines DL, the preparation technique is improved in that after the second interlayer insulating layer and films under the second interlayer insulating layer are prepared and before the first conductive layer 8 is prepared, the second interlayer insulating layer and the films under the second interlayer insulating layer may be etched so that at least part of the insulating layers corresponding to the transparent region S1 and the first circuit region S2 are removed, and then the first conductive layer 8 is prepared and the source SE, the drain DE, and the data lines DL of the thin-film transistor are formed so that the number of the insulating layers between the first conductive layer 8 and the substrate 10 in the first circuit region S2 is smaller than the number of the insulating layers between the first conductive layer 8 and the substrate 10 in the first device region S3.

FIG. 17 is another cross-sectional view of the array substrate taken along AA′ in FIG. 1. As shown in FIG. 17, in some embodiments, the driving layer includes the multiple insulating layers disposed between the first conductive layer 8 and the substrate 10; and the thickness of at least one insulating layer in the first circuit region S2 along the thickness direction D3 of the array substrate is smaller than the thickness of the at least one insulating layer in the first device region S3 along the thickness direction D3 of the array substrate. Specifically, in this embodiment, the thickness of the at least one insulating layer between the first conductive layer 8 and the substrate 10 in the first circuit region S2 may be reduced so that the thickness of the insulating layer in the first circuit region S2 is smaller than the thickness of the insulating layer in the first device region S3. Thus, the thickness of the driving layer in the first circuit region S2 can be smaller than the thickness of the driving layer in the first device region S3, thereby achieving the effect of reducing the risk of film breakage of the light-shielding layer 3 in the first circuit region S2 and preventing the bonding yield of the light-emitting element in the first device region S3 from being affected.

For example, referring to FIG. 17, when the first conductive layer 8 includes the data lines DL, the film thickness of the at least one of the spacer layer 201, the gate insulating layer 203, the first interlayer insulating layer 205, or the second interlayer insulating layer 207 between the data lines DL and the substrate 10 in the first circuit region S2 may be configured to be smaller than the thickness of the film in the first device region S3. For example, FIG. 17 illustrates an example in which the thicknesses of the spacer layer 201, the gate insulating layer 203, the first interlayer insulating layer 205, and the second interlayer insulating layer 207 between the data lines DL and the substrate 10 in the first circuit region S2 are smaller than the thicknesses of the corresponding films in the first device region S3, which is conducive to effectively reducing the overall thickness of the driving layer in the first circuit region S2, ensures the thickness of the light-shielding layer 3 in the first circuit region S2, and reduces the risk of film breakage.

It is to be noted that in other embodiments, for the multiple insulating layers between the first conductive layer 8 and the first substrate 10 in the first circuit region S2, part of the films may be removed and part of the films may be thinned. For example, referring to FIG. 16, when the first conductive layer 8 includes the data lines DL, the gate insulating layer 203, the first interlayer insulating layer 205, and the second interlayer insulating layer 207 between the data lines DL and the substrate 10 may be removed and the spacer layer 201 may be thinned so that the data lines DL can be prevented from being in direct contact with the substrate 10 and the thickness of the driving layer in the entire first circuit region S2 can be further reduced.

Referring to FIG. 15, in some embodiments, the driving layer includes the first conductive layer 8, where the first conductive layer 8 includes a first surface f1 and a second surface f2 which are parallel to the substrate 10, the first surface f1 of the first conductive layer 8 is facing the substrate 10 and the second surface f2 of the first conductive layer 8 is facing away from the substrate 10. The light-shielding layer 3 includes a third surface f3 and a fourth surface f4 which are parallel to the substrate 10, and the third surface f3 is disposed on the side of the light-shielding layer 3 facing the substrate 10 and the fourth surface f4 of the light-shielding layer 3 is facing away from the substrate 10. The distance d7 between the first surface f1 and the third surface f3 in the first circuit region S2 along the thickness direction D3 of the array substrate is less than the distance d8 between the first surface f1 and the third surface f3 in the first device region S3 along the thickness direction D3 of the array substrate.

Specifically, as shown in FIG. 15, the first surface f1 of the first conductive layer is used as a boundary, and the thickness d5 of the driving layer on the side of the first conductive layer 8 in the first circuit region S2 facing the substrate 10 is reduced such that it is implemented that the thickness d3 of the driving layer in the entire first circuit region S2 is smaller than the thickness d4 of the driving layer in the entire first device region S3 in the preceding embodiment while the thickness d7 of the driving layer on the side of the first surface f1 of the first conductive layer 8 in the first circuit region S2 facing away from the substrate 10 is reduced such that it is implemented that the thickness d3 of the driving layer in the entire first circuit region S2 is smaller than the thickness d4 of the driving layer in the entire first device region S3 in this embodiment.

Referring to the preceding embodiment, the insulating films may be removed or thinned such that it is implemented that the distance d7 between the first surface f1 and the third surface f3 in the first circuit region S2 is less than the distance d8 between the first surface f1 and the third surface f3 in the first device region S3 in this embodiment.

For example, FIG. 18 is another cross-sectional view of the array substrate taken along AA′ in FIG. 1. As shown in FIG. 18, the array substrate includes the thin-film transistor T and the data lines DL, and the thin-film transistor includes the source SE and the drain DE, where the region in which the thin-film transistor T is disposed overlaps at least the first device region S3 along the thickness direction D3 of the array substrate, and the region in which the data lines DL are disposed overlaps the first circuit region S2 along the thickness direction D3 of the array substrate; and in some embodiments, the first conductive layer 8 is used for forming at least the source SE, the drain DE, and the data lines DL, in other words, the first conductive layer 8 is the first metal layer 208.

Further, with continued reference to FIG. 18, the driving layer includes the organic insulating layer disposed between the first conductive layer 8 and the light-shielding layer 3; and the thickness of the organic insulating layer in the first circuit region S2 along the thickness direction D3 of the array substrate is smaller than the thickness of the organic insulating layer in the first device region S3 along the thickness direction D3 of the array substrate.

In this embodiment, when the first conductive layer 8 is used for forming the source SE, the drain DE, and the data lines DL, the organic insulating layers, such as the preceding first planarization layer 210 and the preceding second planarization layer 212, are further included on the side of the source SE facing away from the substrate 10 in the first device region S3. The first planarization layer 210 and the second planarization layer 212 are also included in the first circuit region S2 and also play an insulating role in the first circuit region S2. Therefore, the organic insulating layer may be thinned such that the thickness of the driving layer in the first circuit region S2 is reduced.

For example, FIG. 18 illustrates an example in which the thickness of the second planarization layer 212 in the first circuit region S2 is smaller than the thickness of the second planarization layer 212 in the first device region S3. In other embodiments, the thickness of the first planarization layer 210 in the first circuit region S2 may be configured to be smaller than the thickness of the first planarization layer 210 in the first device region S3, or the thicknesses of the first planarization layer 210 and the second planarization layer 212 in the first circuit region S2 may be configured to be smaller than the thicknesses of the corresponding films in the first device region S3.

It is to be noted that in other embodiments, both the thicknesses of insulating layers on the side of the first conductive layer 8 in the first circuit region S2 facing the substrate 10 and the thicknesses of insulating layers on the side of the first conductive layer 8 in the first circuit region S2 facing away from the substrate 10 may be reduced so that the thickness of the driving layer in the entire first circuit region S2 is reduced to a greater degree and the problem of film breakage of the first circuit region S2 is effectively alleviated. The thicknesses of the insulating layers may be reduced in the specific manner of removing or thinning the films.

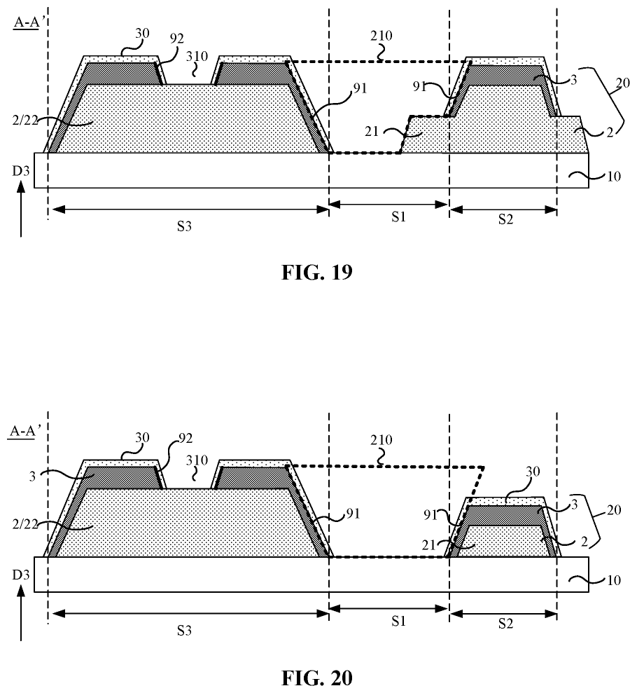

Based on the preceding embodiments, FIG. 19 is another cross-sectional view of the array substrate taken along AA′ in FIG. 1, and FIG. 20 is another cross-sectional view of the array substrate taken along AA′ in FIG. 1. As shown in FIG. 19 or FIG. 20, in some embodiments, the array substrate further includes an organic protective layer 30 disposed on the side of the base layer 20 facing away from the substrate 10 and covering the light-shielding layer 3. Specifically, as shown in FIG. 19, the organic protective layer 30 covers the surface of the side of the light-shielding layer 3 facing away from the substrate 10 and covers the sidewalls 91 of the light-shielding layer 3 which are used for forming the first opening 210 and the sidewalls 92 of the light-shielding layer 3 which are used for forming the second opening 310. In comparison with the case where an inorganic film is used for covering and protecting the light-shielding layer 3, in this embodiment, the organic protective layer 30 is formed of the organic material to protect the light-shielding layer, which can effectively prevent the light-shielding layer 3 from being eroded by solutions in subsequent processes to avoid holes and fading of the light-shielding layer and ensure the light-shielding effect.

For example, the organic protective layer may be made of the transparent OCA. In this case, the preparation procedure of the organic protective layer is substantially the same as the preparation procedure of the light-shielding layer, where the LOCA needs to be coated first. Therefore, the organic protective layer in the first circuit region is also prone to the problem of film breakage. The problem of film breakage of the organic protective layer in the first circuit region can also be solved by using the technical solutions provided by the preceding embodiments, the organic protective layer in the first device region can also be prevented from being excessively thick, and the bonding yield of the light-emitting element in the first device region is prevented from being affected. For example, FIG. 19 illustrates an example in which the at least part of the films of the first driving sub-portion 21 in the first circuit region S2 extend to the transparent region S1, and FIG. 20 illustrates an example in which the thickness of the driving layer 2 in the first circuit region S2 is smaller than the thickness of the driving layer in the first device region S3. For a possible embodiment, reference may be made to the preceding descriptions, and the details are not described here.

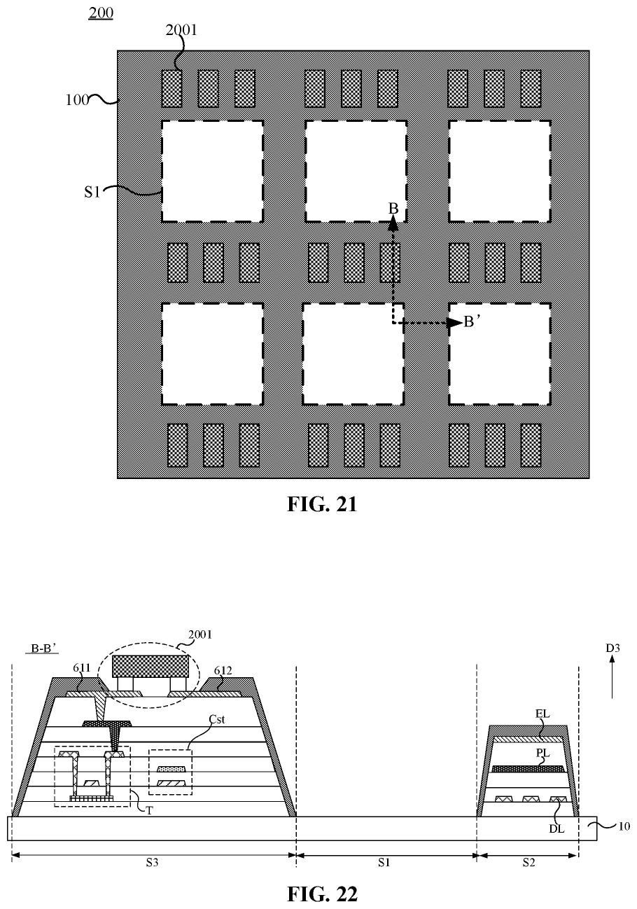

Based on the same inventive concept, an embodiment of the present disclosure further provides a display panel. FIG. 21 is a top view of a display panel according to an embodiment of the present invention, and FIG. 22 is a cross-sectional view of the display panel taken along BB′ in FIG. 21. As shown in FIGS. 21 and 22, a display panel 200 provided by the embodiment of the present disclosure includes multiple light-emitting elements 2001 and the array substrate 100 provided by any one of the preceding embodiments (the array substrate shown in FIG. 16 is used as only an example to illustrate the array substrate in FIG. 22), the light-emitting elements 2001 are electrically connected to the array substrate 100, and the region in which a light-emitting element 2001 is disposed does not overlap a transparent region S1 along the thickness direction D3 of the display panel. For example, a light-emitting element 2001 may be a micro light-emitting diode. As shown in FIG. 22, the light-emitting element 2001 is electrically connected to a first connection electrode 611 and a second connection electrode 612 in the array substrate, and the light-emitting element 2001 overlaps at least a first device region S3 along the thickness direction D3 of the display panel. Since the display panel provided by the embodiment of the present disclosure includes the array substrate provided by any one of the preceding embodiments, the display panel has the same beneficial effects as the preceding array substrate. For similarities, reference may be made to descriptions in the preceding embodiments of the array substrate. The details are not repeated here.

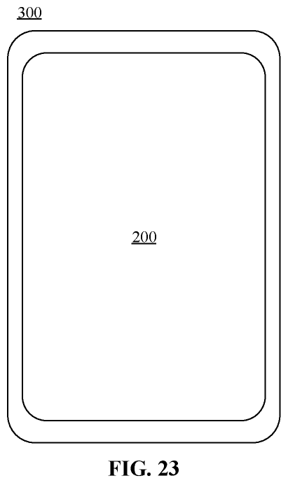

Based on the same inventive concept, an embodiment of the present disclosure further provides a display device. FIG. 23 is a structural diagram of a display device according to an embodiment of the present invention. As shown in FIG. 23, a display device 300 includes the display panel 200 provided by the preceding embodiment. Thus, the display device 300 has the same beneficial effects as the preceding array substrate. The display device may be a transparent display device applied to any occasion, which is not limited in the embodiment of the present invention.

What is claimed is:

1. An array substrate, comprising a plurality of transparent regions and further comprising:
a substrate; and
a base layer disposed on a side of the substrate and comprising a driving layer and a light-shielding layer disposed on a side of the driving layer facing away from the substrate, wherein a region in which the light-shielding layer is disposed does not overlap the plurality of transparent regions along a thickness direction of the array substrate.

2. The array substrate according to claim 1, wherein the base layer further comprises a plurality of first openings; and
along a direction from the base layer to the substrate and perpendicular to a plane where the substrate is disposed, the plurality of first openings penetrate through at least part of the base layer; and at least part of a first opening of the plurality of first openings is disposed in a respective transparent region of the plurality of transparent regions.

3. The array substrate according to claim 2, further comprising a first circuit region adjacent to a respective transparent region of the plurality of transparent regions along a first direction;
wherein the light-shielding layer comprises a first light-shielding sub-portion, the driving layer comprises a first driving sub-portion, and a region in which the first light-shielding sub-portion is disposed and a region in which the first driving sub-portion is disposed each overlap the respective transparent region along the thickness direction of the array substrate; and
a width of at least part of the first driving sub-portion along the first direction is greater than a width of the first light-shielding sub-portion along the first direction; and
wherein the first direction is parallel to the substrate.

4. The array substrate according to claim 3, wherein the driving layer comprises a plurality of insulating layers, at least one of the plurality of insulating layers comprises a first insulating sub-portion, and a region in which the first insulating sub-portion is disposed overlaps the first circuit region along the thickness direction of the array substrate; and
a width of the first insulating sub-portion along the first direction is greater than the width of the first light-shielding sub-portion along the first direction.

5. The array substrate according to claim 2, further comprising a first circuit region adjacent to a respective transparent region of the plurality of transparent regions along a first direction;
wherein the driving layer comprises a first wiring layer, a region in which the first wiring layer is disposed overlaps the first circuit region and does not overlap the respective transparent region along the thickness direction of the array substrate, the first wiring layer comprises a first wire extending along a second direction, and the first wire in the first circuit region are in contact with the substrate; and
wherein the first direction and the second direction intersect with each other and are each parallel to the substrate.

6. The array substrate according to claim 2, further comprising a first device region and a first circuit region which are adjacent to a respective transparent region of the plurality of transparent regions;
wherein a width of the first circuit region, along a direction from the respective transparent region to the first circuit region, is W1; and a width of the first device region, along a direction from the respective transparent region to the first device region, is W2; and
wherein W1<W2.

7. The array substrate according to claim 6, wherein
the driving layer comprises a first driving sub-portion at least partially disposed in the first circuit region, wherein the first driving sub-portion comprises a first sidewall comprising at least one first sidewall sub-portion, the at least one first sidewall sub-portion continuously inclines towards the first circuit region, and a projection height of a first sidewall sub-portion farthest from the substrate in the thickness direction of the array substrate is L1; and
the driving layer comprises a second driving sub-portion at least partially disposed in the first device region, wherein the second driving sub-portion comprises a second sidewall comprising one second sidewall sub-portion, the one second sidewall sub-portion continuously inclines towards the first device region, and a projection height of the one second sidewall sub-portion in the thickness direction of the array substrate is L2; and
wherein L1<L2.

8. The array substrate according to claim 6, wherein
a thickness of the driving layer in the first circuit region along the thickness direction of the array substrate is smaller than a thickness of the driving layer in the first device region along the thickness direction of the array substrate.

9. The array substrate according to claim 8, wherein the driving layer comprises a first conductive layer, and along the thickness direction of the array substrate, a distance between the first conductive layer in the first circuit region and the substrate is less than a distance between the first conductive layer in the first device region and the substrate,
or,
wherein the driving layer comprises a first conductive layer, the first conductive layer comprises a first surface and a second surface which are parallel to the substrate, the first surface of the first conductive layer is facing the substrate and the second surface of the first conductive layer is facing away from the substrate, the light-shielding layer comprises a third surface and a fourth surface which are parallel to the substrate, the third surface of the light-shielding layer is facing the substrate and the fourth surface of the light-shielding layer is facing away from the substrate, and a distance between the first surface and the third surface in the first circuit region along the thickness direction of the array substrate is less than a distance between the first surface and the third surface in the first device region along the thickness direction of the array substrate.

10. The array substrate according to claim 9, wherein in a case where along the thickness direction of the array substrate, the distance between the first conductive layer in the first circuit region and the substrate is less than the distance between the first conductive layer in the first device region and the substrate, the driving layer comprises a plurality of insulating layers disposed between the first conductive layer and the substrate, and among the plurality of insulating layers, a number of insulating layers in the first circuit region is smaller than a number of insulating layers in the first device region,
or,
wherein in a case where along the thickness direction of the array substrate, the distance between the first conductive layer in the first circuit region and the substrate is less than the distance between the first conductive layer in the first device region and the substrate, the driving layer comprises a plurality of insulating layers disposed between the first conductive layer and the substrate, and along the thickness direction of the array substrate, a thickness of at least one insulating layer of the plurality of insulating layers in the first circuit region is smaller than a thickness of the at least one insulating layer in the first device region,
or,
wherein in a case where the distance between the first surface and the third surface in the first circuit region along the thickness direction of the array substrate is less than the distance between the first surface and the third surface in the first device region along the thickness direction of the array substrate, the driving layer comprises an organic insulating layer disposed between the first conductive layer and the light-shielding layer, and a thickness of the organic insulating layer in the first circuit region along the thickness direction of the array substrate is smaller than a thickness of the organic insulating layer in the first device region along the thickness direction of the array substrate.

11. The array substrate according to claim 9, comprising a thin-film transistor and data lines, wherein a region in which the thin-film transistor is disposed overlaps at least the first device region along the thickness direction of the array substrate, and a region in which the data lines are disposed overlaps the first circuit region along the thickness direction of the array substrate; and,
wherein the thin-film transistor comprises a source and a drain; and the first conductive layer is at least used for forming the source of the thin-film transistor, the drain of the thin-film transistor, and the data lines.

12. The array substrate according to claim 8, wherein a side of the first opening closest to the substrate coincides with a region in which the transparent region is disposed.

13. The array substrate according to claim 6, wherein a region in which the driving layer is disposed in the first device region does not overlap the transparent region along the thickness direction of the array substrate; and at least one film of the driving layer in the first circuit region extends to the transparent region.

14. The array substrate according to claim 13, wherein the driving layer comprises a plurality of insulating layers, and at least one insulating layer of the plurality of insulating layers in the first circuit region extends to the transparent region,
or,
wherein the driving layer comprises transparent wiring layers, and at least one of the transparent wiring layers in the first circuit region extends to the transparent region,
or,
wherein the driving layer comprises a first driving sub-portion and a second driving sub-portion, wherein a region in which the first driving sub-portion is disposed overlaps the first circuit region along the thickness direction of the array substrate, and a region in which the second driving sub-portion is disposed overlaps the first device region along the thickness direction of the array substrate, and a maximum width of the first driving sub-portion, along the direction from the transparent region to the first circuit region, is H1, and a maximum width of the second driving sub-portion, along the direction from the transparent region to the first device region, is H2, and H1≥H2.

15. The array substrate according to claim 6, wherein the first circuit region is configured to be adjacent to the transparent region along a first direction, and the first device region is configured to be adjacent to the transparent region along a second direction, wherein the first direction and the second direction intersect with each other and are each parallel to the substrate.

16. The array substrate according to claim 2, further comprising a first device region adjacent to the transparent region along a second direction, wherein the second direction is parallel to the substrate;
wherein the driving layer comprises a connection electrode layer comprising a plurality of groups of connection electrodes, and a region in which the plurality of groups of connection electrodes are disposed overlaps the first device region along the thickness direction of the array substrate; and
the light-shielding layer comprises a plurality of groups of second openings, and one group of connection electrodes of the plurality of groups of connection electrodes are exposed by a respective group of second openings of the plurality of groups of second openings.

17. The array substrate according to claim 16, wherein at least one first device region is adjacent to two first openings of the plurality of first openings along the second direction, a second opening of the plurality of groups of second openings along the second direction comprises a first edge and a second edge which are opposite to each other, sides of two adjacent first openings which are farthest from the substrate separately comprise a third edge and a fourth edge, the third edge and the fourth edge are opposite to each other and are disposed in the first device region, the first edge is adjacent to the third edge along the second direction, the second edge is adjacent to the fourth edge along the second direction, and a distance between the first edge and the third edge along the second direction is equal to a distance between the second edge and the fourth edge along the second direction,
or,
wherein the array substrate further comprises an organic protective layer covering a surface of a side of the light-shielding layer facing away from the substrate and covering sidewalls of the light-shielding layer which are used for forming the plurality of first openings and the plurality of groups of second openings,
or,
wherein a connection electrode of the plurality of groups of connection electrodes comprises a first connection electrode and a second connection electrode, a group of second openings of the plurality of groups of second openings comprise at least one second sub-opening, and at least one of the first connection electrode or the second connection electrode is exposed by one sub-opening of the at least one second sub-opening.

18. The array substrate according to claim 1, further comprising an organic protective layer covering the light-shielding layer and disposed on a side of the base layer facing away from the substrate.

19. A display panel, comprising a plurality of light-emitting elements and an array substrate, wherein the plurality of light-emitting elements are electrically connected to the array substrate, and regions in which the plurality of light-emitting elements are disposed do not overlap the plurality of transparent regions along the thickness direction of the display panel; and,
wherein the array substrate comprises a plurality of transparent regions and further comprises
a substrate; and
a base layer disposed on a side of the substrate and comprising a driving layer and a light-shielding layer disposed on a side of the driving layer facing away from the substrate, wherein a region in which the light-shielding layer is disposed does not overlap the plurality of transparent regions along a thickness direction of the array substrate.

20. A display device, comprising a display panel,
wherein the display panel comprises a plurality of light-emitting elements and an array substrate, wherein the plurality of light-emitting elements are electrically connected to the array substrate, and regions in which the plurality of light-emitting elements are disposed do not overlap the plurality of transparent regions along the thickness direction of the display panel; and,
wherein the array substrate comprises a plurality of transparent regions and further comprises
a substrate; and a base layer disposed on a side of the substrate and comprising a driving layer and a light-shielding layer disposed on a side of the driving layer facing away from the substrate, wherein a region in which the light-shielding layer is disposed does not overlap the plurality of transparent regions along a thickness direction of the array substrate.
